(19) United States
(12) Patent Application Publication
(10) Pub. No.: US 2025/0127017 A1
(43) Pub. Date: Apr. 17, 2025

(54) DISPLAY PANEL AND METHOD OF MANUFACTURING THE SAME

(71) Applicant: Samsung Display Co., LTD., Yongin-si (KR)

(72) Inventor: HYUNEOK SHIN, Yongin-si (KR)

(21) Appl. No.: 18/808,480

(22) Filed: Aug. 19, 2024

(30) Foreign Application Priority Data
Oct. 11, 2023 (KR) 10-2023-0135393

(51) Int. Cl. H10K 59/80; H10K 59/12; H10K 59/122

(52) U.S. Cl. CPC H10K 59/873; H10K 59/1201; H10K 59/122

(57) ABSTRACT

A display panel includes a base layer, a pixel definition layer disposed on the base layer and having a light emitting opening defined therethrough, a barrier wall disposed on the pixel definition layer, having a conductivity, and provided with a barrier wall opening defined therethrough and corresponding to the light emitting opening, a light emitting element disposed in the light emitting opening and including an anode, an intermediate layer disposed on the anode, an electron control layer disposed on the intermediate layer, and a cathode disposed on the electron control layer and connected to the barrier wall, a first pattern spaced apart from the electron control layer, being in contact with an upper surface of the barrier wall, and including a same material as the electron control layer, and a second pattern spaced apart from the cathode, disposed on the first pattern, and including a same material as the cathode.

This application claims priority to Korean Patent Application No. 10-2023-0135393, filed on Oct. 11, 2023, and all the benefits accruing therefrom under 35 U.S.C. § 119, the content of which in its entirety is herein incorporated by reference.

### BACKGROUND

### 1. Field of Disclosure

The present invention relates to a display panel and a method of manufacturing the same, and more particularly, to a display panel with an improved display quality and a method of manufacturing the display panel.

### 2. Description of the Related Art

Display devices that provide images to a user, such as a television set, a monitor, a smart phone, and a tablet computer, include a display panel which is used to display the images. Various types of display panels, such as a liquid crystal display panel, an organic light emitting display panel, an electrowetting display panel, and an electrophoretic display panel, are being developed.

The organic light emitting display panel includes an anode, a cathode, and a light emitting pattern. The light emitting pattern is disposed in each light emitting area after being divided into plural portions, and the cathode provides a common voltage to each light emitting area.

### SUMMARY

The present invention provides a display panel with an improved display quality, which includes a light emitting element formed without using a metal mask.

The present invention provides a method of manufacturing the display panel.

Embodiments of the invention provide a display panel including a base layer, a pixel definition layer disposed on the base layer and provided with a light emitting opening defined therethrough, a barrier wall disposed on the pixel definition layer, having a conductivity, and provided with a barrier wall opening defined therethrough and corresponding to the light emitting opening, a light emitting element disposed in the light emitting opening and including an anode, an intermediate layer disposed on the anode, an electron control layer disposed on the intermediate layer, and a cathode disposed on the electron control layer and connected to the barrier wall, a first pattern spaced apart from the electron control layer, being in contact with an upper surface of the barrier wall, and including a same material as the electron control layer, and a second pattern spaced apart from the cathode, disposed on the first pattern, and including a same material as the cathode.

In an embodiment, the first pattern entirely covers the upper surface of the barrier wall, and the second pattern entirely covers an upper surface of the first pattern.

In an embodiment, the second pattern is in contact with the upper surface of the first pattern.

In an embodiment, the display panel further includes an encapsulation layer covering the light emitting element, wherein the encapsulation layer entirely covers an upper surface of the second pattern.

In an embodiment, the encapsulation layer entirely covers a side surface of the first pattern and a side surface of the second pattern.

In an embodiment, the barrier wall has an undercut shape when viewed in a cross-section.

In an embodiment, the display panel further includes a first encapsulation layer covering the light emitting element, a monomer covering the first encapsulation layer, and a second encapsulation layer covering the monomer.

In an embodiment, the intermediate layer includes a hole control layer disposed on the anode and a light emitting layer disposed on the hole control layer and including a light emitting material.

Embodiments of the invention provide a display panel including a base layer, a pixel definition layer disposed on the base layer and provided with a plurality of light emitting openings defined therethrough and spaced apart from each other, a barrier wall disposed on the pixel definition layer, having a conductivity, and provided with a plurality of barrier wall openings defined therethrough and corresponding to the light emitting openings, a first light emitting element disposed in a first light emitting opening among the plurality of light emitting openings and including a first anode, a first intermediate layer disposed on the first anode and including a first light emitting material generating a light having a first color, a first electron control layer disposed on the first intermediate layer, and a first cathode disposed on the first electron control layer and connected to the barrier wall, a second light emitting element disposed in a second light emitting opening among the plurality of light emitting openings and including a second anode, a second intermediate layer disposed on the second anode and including a second light emitting material generating a light having a second color, a second electron control layer disposed on the second intermediate layer, and a second cathode disposed on the second electron control layer and connected to the barrier wall, a first pattern spaced apart from the first electron control layer and the second electron control layer, being in contact with an upper surface of the barrier wall, and including the same material as the first electron control layer and the second electron control layer, and a second pattern spaced apart from the first cathode and the second cathode, disposed on the first pattern, and including the same material as the first cathode and the second cathode.

In an embodiment, the display panel further includes an encapsulation layer covering the first light emitting opening, the second light emitting opening, and the barrier wall, wherein the encapsulation layer entirely covers an upper surface of the second pattern.

In an embodiment, the first pattern entirely covers the upper surface of the barrier wall, and the second pattern entirely covers an upper surface of the first pattern.

In an embodiment, the first intermediate layer includes a first hole control layer disposed on the first anode and a first light emitting layer disposed on the first hole control layer and including the first light emitting material. The second intermediate layer includes a second hole control layer disposed on the second anode and a second light emitting layer disposed on the second hole control layer and including the second light emitting material.

Embodiments of the invention provide a method of manufacturing a display panel. The method includes providing a preliminary display panel including a base layer, an anode disposed on the base layer, and a preliminary pixel definition layer disposed on the base layer and covering the anode. The method further includes forming a barrier wall through which a plurality of barrier wall openings is defined, wherein the barrier wall is disposed on the preliminary pixel definition layer. The method also includes patterning the preliminary pixel definition layer to form a pixel definition layer through which a plurality of light emitting openings respectively corresponding to the barrier wall openings and exposing at least a portion of the anode is defined, and forming first and second intermediate layers respectively including first and second light emitting materials respectively generating lights having first and second colors which are different from each other, first and second electron control layers overlapping the first and second intermediate layers, and a first pattern separated from the first and second electron control layers and being in contact with an upper surface of the barrier wall via the plurality of barrier wall openings. The first pattern is substantially simultaneously formed with the first electron control layer, and the second intermediate layer is formed after the first intermediate layer is formed and before the first pattern is formed.

In an embodiment, the method further includes forming a cathode disposed on the first and second intermediate layers and being in contact with the barrier wall, and a second pattern separated from the cathode and being disposed on the first pattern, wherein the second pattern is substantially simultaneously formed with the cathode.

In an embodiment, the method further includes forming a first preliminary intermediate layer on the anode and the barrier wall, forming a first protective layer on the first preliminary intermediate layer, forming a first photoresist pattern covering a first light emitting opening among the plurality of light emitting openings, removing the first protective layer to form a first protective pattern, and removing the first preliminary intermediate layer and the first photoresist pattern to form the first intermediate layer.

In an embodiment, the method further includes forming a second preliminary intermediate layer on the anode, the first intermediate layer, and the barrier wall, forming a second protective layer on the second preliminary intermediate layer, forming a second photoresist pattern covering a second light emitting opening among the plurality of light emitting openings, removing the second protective layer to form a second protective pattern, and removing the second preliminary intermediate layer and the second photoresist pattern to form the second intermediate layer, wherein the first and second protective patterns are removed, and forming a second pattern, a first cathode disposed in the first light emitting opening, and a second cathode disposed in the second light emitting opening.

In an embodiment, the first protective layer is formed by a thermal evaporation process.

In an embodiment, the first protective layer is removed by a wet etching process.

In an embodiment, the method further includes forming an encapsulation layer covering the barrier wall openings, wherein the encapsulation layer covers a first light emitting opening and a second light emitting opening which is spaced apart from the first light emitting opening among the plurality of light emitting openings.

In an embodiment, the forming of the barrier wall includes forming a first layer on the pixel definition layer, forming a second layer on the first layer, patterning the first layer and the second layer to form a barrier wall pattern, and patterning the barrier wall pattern to form an undercut in the barrier wall pattern.

According to an embodiment, the display panel includes a light emitting element that is formed without using a metal mask.

According to an embodiment, the display panel includes a light emitting element with an improved process reliability.

According to an embodiment, a light emitting element of the display panel has an improved electrical connection reliability.

According to an embodiment, a light emitting element is formed without excessively etching the encapsulation layer.

According to an embodiment, the light emitting element includes an electron control layer and a cathode that are substantially simultaneously formed in multiple light emitting openings.

According to an embodiment, the protective layer covers the intermediate layer and prevents the intermediate layer from being damaged.

According to an embodiment, an electron control layer and a cathode are substantially simultaneously formed in multiple light emitting openings through the protective layer covering the intermediate layer.

### BRIEF DESCRIPTION OF THE DRAWINGS

The above and other advantages of the present disclosure will become readily apparent by reference to the following detailed description when considered in conjunction with the accompanying drawings wherein:

FIG. 1A is a perspective view of a display device, according to an embodiment;

FIG. 1B is an exploded perspective view of a display device, according to an embodiment;

FIG. 2 is a cross-sectional view of a display module, according to an embodiment;

FIG. 3 is a plan view of a display panel, according to an embodiment;

FIG. 4 is a schematic of an equivalent circuit diagram of a pixel, according to an embodiment;

FIG. 5 is an enlarged plan view of a portion of a display panel, according to an embodiment;

FIG. 6 is a cross-sectional view of a portion of a display panel, according to an embodiment;

FIG. 7 is a cross-sectional view of a portion of a display panel, according to an embodiment;

FIG. 8A is a cross-sectional view illustrating a method of manufacturing a display panel, according to an embodiment;

FIG. 8B is a cross-sectional view illustrating a method of manufacturing a display panel, according to an embodiment;

FIG. 8C is a cross-sectional view illustrating a method of manufacturing a display panel, according to an embodiment;

FIG. 8D is a cross-sectional view illustrating a method of manufacturing a display panel, according to an embodiment;

FIG. 8E is a cross-sectional view illustrating a method of manufacturing a display panel, according to an embodiment;

FIG. 8F is a cross-sectional view illustrating a method of manufacturing a display panel, according to an embodiment;

FIG. 8G is a cross-sectional view illustrating a method of manufacturing a display panel, according to an embodiment;

FIG. 8H is a cross-sectional view illustrating a method of manufacturing a display panel, according to an embodiment;

FIG. 9A is a cross-sectional view illustrating a method of manufacturing a display panel, according to an embodiment;

FIG. 9B is a cross-sectional view illustrating a method of manufacturing a display panel, according to an embodiment;

FIG. 9C is a cross-sectional view illustrating a method of manufacturing a display panel, according to an embodiment;

FIG. 9D is a cross-sectional view illustrating a method of manufacturing a display panel, according to an embodiment;

FIG. 9E is a cross-sectional view illustrating a method of manufacturing a display panel, according to an embodiment; and

FIG. 9F is a cross-sectional view illustrating a method of manufacturing a display panel, according to an embodiment.

### DETAILED DESCRIPTION

In the present invention, it will be understood that when an element (or area, layer, or portion) is referred to as being “on”, “connected to” or “coupled to” another element or layer, it can be disposed directly on, connected or coupled to the other element or layer or intervening elements or layers may be present.

Like numerals refer to like elements throughout. In the drawings, the thickness, ratio, and dimension of components may be exaggerated for effective description of the technical content. As used herein, the term “and/or” may include any and all combinations of one or more of the associated listed items.

It will be understood that, although the terms first, second, etc. may be used herein to describe various elements, these elements should not be limited by these terms. These terms are only used to distinguish one element from another element. Thus, a first element discussed below could be termed a second element without departing from the teachings of the present disclosure. As used herein, the singular forms, “a”, “an” and “the” are intended to include the plural forms as well, unless the context clearly indicates otherwise.

Spatially relative terms, such as “beneath”, “below”, “lower”, “above”, “upper” and the like, may be used herein for ease of description to describe one element or feature's relationship to another elements or features as shown in the figures.

It will be further understood that the terms “include” and/or “including”, when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms including technical and scientific terms used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the present invention will be described with reference to accompanying drawings.

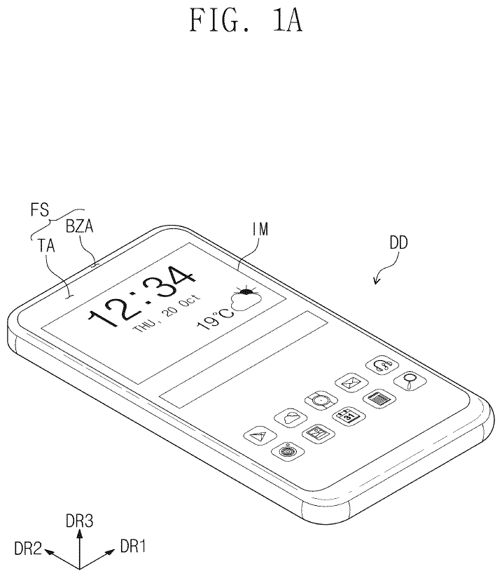

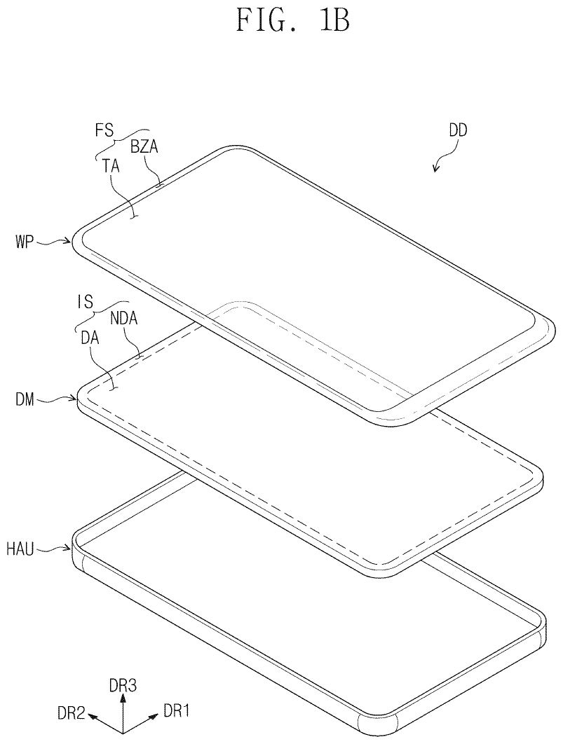

FIG. 1A is a perspective view of a display device DD, according to an embodiment. FIG. 1B is an exploded perspective view of the display device DD, according to an embodiment.

In an embodiment, the display device DD may be applied to a large-sized electronic item, such as a television set, a monitor, or an outdoor billboard. In addition, the display device DD may be applied to a small and medium-sized electronic item, such as a personal computer, a notebook computer, a personal digital assistant, a car navigation unit, a game unit, a smartphone, a tablet computer, and a camera. However, these are merely examples, and the display device DD may be employed in other electronic items as well. In the present embodiment, the smartphone will be described as a representative example of the display device DD.

In an embodiment and referring to FIGS. 1A and 1B, the display device DD may display an image IM through a display surface FS, which is directed to be substantially parallel to each of a first direction DR1 and a second direction DR2, and toward a third direction DR3. The image IM may include a video and a still image. FIG. 1A shows a clock widget and application icons as a representative example of the image IM. The display surface FS through which the image IM is displayed may correspond to a front surface of the display device DD.

In an embodiment, front (or upper) and rear (or lower) surfaces of each member of the display device DD may be defined with respect to a direction in which the image IM is displayed. The front and rear surfaces may be directed opposite to each other in the third direction DR3, and a normal line direction of each of the front and rear surfaces may be directed substantially parallel to the third direction DR3. Meanwhile, directions indicated by the first, second, and third directions DR1, DR2, and DR3, respectively, may be relative to each other and may be changed to other directions. In the following descriptions, the expression “when viewed in a plane” means a state of being viewed in the third direction DR3.

In an embodiment, the display device DD may include a window WP, a display module DM, and a housing HAU. The window WP and the housing HAU may be coupled to each other to provide an exterior of the display device DD.

The window WP may include an optically transparent insulating material. For example, in an embodiment, the window WP may include a glass or plastic material, where a front surface of the window WP may define the display surface FS of the display device DD. The display surface FS may include a transmissive area TA and a bezel area BZA, where the transmissive area TA may be an optically transparent area. As an example, the transmissive area TA may be an area having a visible light transmittance of about 90% or more.

In an embodiment, the bezel area BZA may be an area having a relatively lower transmittance than the transmittance of the transmissive area TA. The bezel area BZA may define a shape of the transmissive area TA. The bezel area BZA may be disposed adjacent to the transmissive area TA and may be disposed to surround the transmissive area TA. However, this is merely an example, and in another embodiment, the bezel area BZA may be omitted from the window WP. The window WP may include at least one functional layer of an anti-fingerprint layer, a hard coating layer, and an anti-reflective layer and should not be particularly limited.

The display module DM may be disposed under the window WP and may have a configuration that substantially generates the image IM. The image IM generated by the display module DM may be displayed through a display surface IS of the display module DM and may be viewed by a user through the transmissive area TA.

The display module DM may include a display area DA and a non-display area NDA, where the display area DA may be activated in response to an electrical signal. The non-display area NDA may be disposed adjacent to the display area DA and may surround the display area DA. The non-display area NDA may be covered by the bezel area BZA and may not be viewed from the outside.

The housing HAU may be coupled with the window WP. The housing HAU and the window WP, which may be coupled to each other, may provide a predetermined inner space which may accommodate the display module DM.

The housing HAU may include a material with a relatively high rigidity. As an example, in an embodiment, the housing HAU may include a frame and/or a plate formed of glass, plastic, metal material, or any combination thereof. The housing HAU may stably protect the components of the display device DD which are accommodated in the inner space from any external impacts.

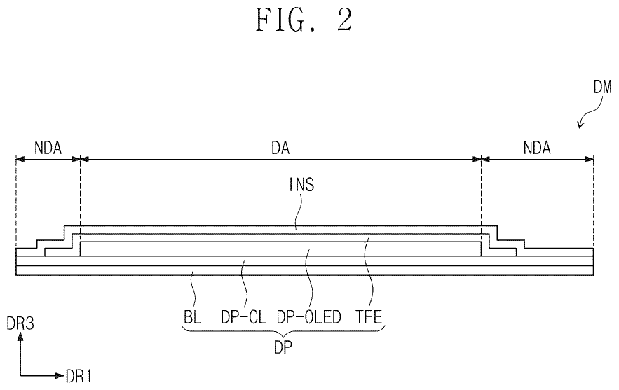

FIG. 2 is a cross-sectional view of the display module DM, according to an embodiment.

Referring to FIG. 2, the display module DM may include a display panel DP and an input sensor INS. Although not shown in the figures, embodiments of the display device DD (refer to FIG. 1A) may include one or more of a protective member disposed on a lower surface of the display panel DP or an anti-reflective member and/or a window member disposed on an upper surface of the input sensor INS.

The display panel DP may be a light emitting type display panel, however, it should not be particularly limited. For example, the display panel DP may be an organic light emitting display panel or an inorganic light emitting display panel. A light emitting layer of the organic light emitting display panel may include an organic light emitting material. A light emitting layer of the inorganic light emitting display panel may include a quantum dot, a quantum rod, or a micro-LED. Hereinafter, the organic light emitting display panel will be described as the display panel DP.

The display panel DP may include a base layer BL, a circuit element layer DP-CL, a display element layer DP-OLED, and a thin film encapsulation layer TFE, where the circuit element layer DP-CL, the display element layer DP-OLED, and the thin film encapsulation layer TFE may be disposed on the base layer BL. The input sensor INS may be disposed directly on the thin film encapsulation layer TFE. In the present disclosure, the expression “A component A is disposed directly on a component B.” means that no adhesive layers are present between the component A and the component B.

The base layer BL may include at least one plastic film, where the base layer BL may be a flexible substrate and may include a plastic substrate, a glass substrate, a metal substrate, or an organic/inorganic composite material substrate. The display area DA and the non-display area NDA described with reference to FIG. 1B may be defined equally in the base layer BL.

In an embodiment, the circuit element layer DP-CL may include at least one insulating layer and a circuit element, where the insulating layer may include at least one inorganic layer and at least one organic layer and where the circuit element may include signal lines and a pixel driving circuit.

The display element layer DP-OLED may include a barrier wall and a light emitting element, where the light emitting element may include an anode, an intermediate layer, and a cathode.

The thin film encapsulation layer TFE may include a plurality of thin layers, where some thin layers may be disposed to improve an optical efficiency, and some thin layers may be disposed to protect organic light emitting diodes.

In an embodiment, the input sensor INS may obtain coordinate information of an external input. The input sensor INS may have a multi-layer structure and may include a conductive layer having a single-layer or multi-layer structure. The input sensor INS may include an insulating layer having a single-layer or multi-layer structure. Moreover, although the input sensor INS may sense the external input by a capacitive method, the invention is not be limited thereto or thereby. As an example, in another embodiment, the input sensor INS may sense the external input by an electromagnetic induction method or a pressure sensing method. Meanwhile, according to still another embodiment, the input sensor INS may be omitted.

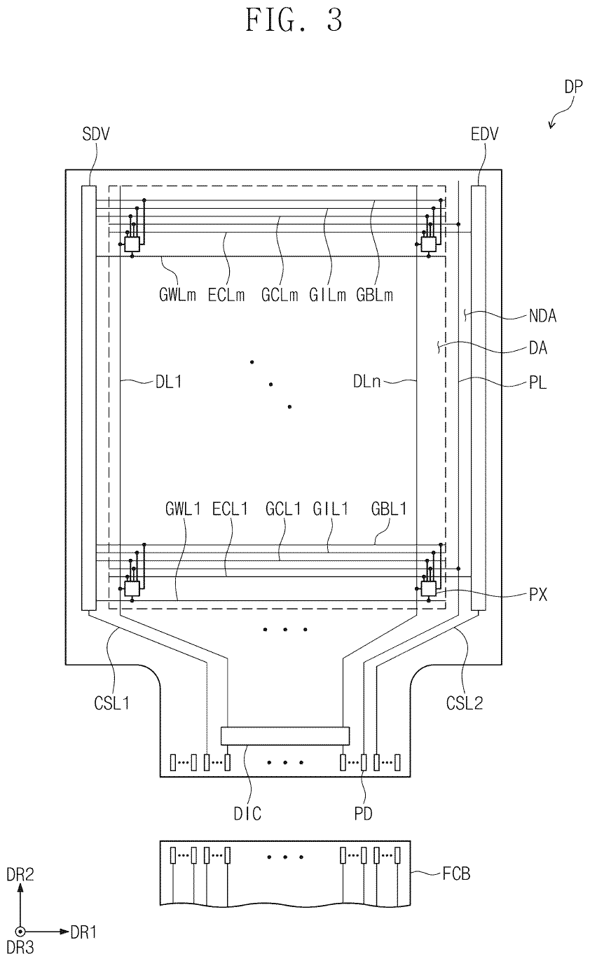

FIG. 3 is a plan view of the display panel DP, according to an embodiment.

In an embodiment and referring to FIG. 3, the display panel DP may include the display area DA and the non-display area NDA which is disposed around the display area DA. The display area DA and the non-display area NDA may be distinguished from each other by a presence or absence of pixels PX, where the pixels PX may be disposed in the display area DA. A scan driver SDV, a data driver, and an emission driver EDV may be disposed in the non-display area NDA, where the data driver may be a circuit provided in a driving chip DIC.

The display panel DP may include the pixels PX, a plurality of initialization scan lines GIL1 to GILm, a plurality of compensation scan lines GCL1 to GCLm, a plurality of write scan lines GWL1 to GWLm, a plurality of black scan lines GBL1 to GBLm, a plurality of emission control lines ECL1 to ECLm, a plurality of data lines DL1 to DLn, first and second control lines CSL1 and CSL2, respectively, a driving voltage line PL, and a plurality of pads PD. In the present disclosure, each of the “m” and the “n” may be a natural number equal to or greater than 2.

The pixels PX may be connected to the initialization scan lines GIL1 to GILm, the compensation scan lines GCL1 to GCLm, the write scan lines GWL1 to GWLm, the black scan lines GBL1 to GBLm, the emission control lines ECL1 to ECLm, and the data lines DL1 to DLn.

The initialization scan lines GIL1 to GILm, the compensation scan lines GCL1 to GCLm, the write scan lines GWL1 to GWLm, and the black scan lines GBL1 to GBLm may extend in a direction that is parallel to an opposite direction of the first direction DR1 and may be electrically connected to the scan driver SDV. The data lines DL1 to DLn may extend in a direction that is parallel to an opposite direction of the second direction DR2 and may be electrically connected to the driving chip DIC. The emission control lines ECL1 to ECLm may extend in the first direction DR1 and may be electrically connected to the emission driver EDV.

The driving voltage line PL may include a portion which extends in the first direction DR1 and a portion which extends in the second direction DR2. The portion extending in the first direction DR1 and the portion extending in the second direction DR2 may be disposed on different layers from each other. The driving voltage line PL may provide a driving voltage to the pixels PX.

The first control line CSL1 may be connected to the scan driver SDV and the second control line CSL2 may be connected to the emission driver EDV.

The driving chip DIC, the driving voltage line PL, the first control line CSL1, and the second control line CSL2 may be electrically connected to the pads PD. Additionally, a flexible circuit film FCB may be electrically connected to the pads PD through an anisotropic conductive adhesive layer. The pads PD may connect the flexible circuit film FCB to the display panel DP. The pads PD may be connected to corresponding pixels PX through the driving voltage line PL, the first control line CSL1, and the second control line CSL2.

In addition, the pads PD may further include input pads where the input pads may connect the flexible circuit film FCB to the input sensor INS (refer to FIG. 2). However, the invention should not be limited thereto or thereby. According to another embodiment, the input pads may be disposed in the input sensor INS and may be connected to a circuit board different from the circuit board to which the pads PD are connected. According to still another embodiment, the input sensor INS may be omitted, and the pads PD may not further include the input pads.

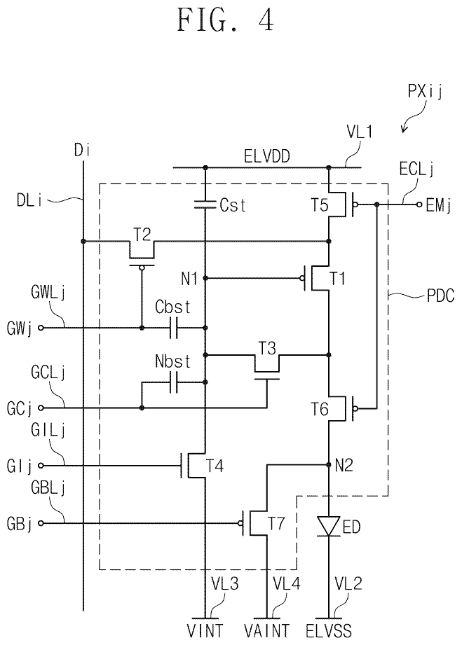

FIG. 4 is an equivalent circuit diagram of a pixel Pxij, according to an embodiment.

FIG. 4 shows an embodiment of an equivalent circuit diagram of the pixel PXij among the pixels PX of FIG. 3. Since the pixels PX have substantially the same configuration as each other, the circuit configuration of the pixel PXij will be described in detail, and detailed descriptions of the other pixels will be omitted.

In an embodiment and referring to FIGS. 3 and 4, the pixel PXij may be connected to an i-th data line DLi among the data lines DL1 to DLn, a j-th initialization scan line GILj among the initialization scan lines GIL1 to GILm, a j-th compensation scan line GCLj among the compensation scan lines GCL1 to GCLm, a j-th write scan line GWLj among the write scan lines GWL1 to GWLm, a j-th black scan line GBLj among the black scan lines GBL1 to GBLm, a j-th emission control line ECLj among the emission control lines ECL1 to ECLm, first and second driving voltage lines VL1 and VL2, respectively, and first and second initialization voltage lines VL3 and VL4, respectively. The “i” may be an integer number equal to or greater than 1 and equal to or smaller than n, and the “j” may be an integer number equal to or greater than 1 and equal to or smaller than m.

In an embodiment, the pixel PXij may include a light emitting element ED and a pixel circuit PDC where the light emitting element ED may be a light emitting diode. In another embodiment, the light emitting element ED may be an organic light emitting diode including an organic light emitting layer, however, it should not be particularly limited. The pixel circuit PDC may control an amount of current flowing through the light emitting element ED in response to a data signal Di. The light emitting element ED may emit a light having a predetermined luminance which corresponds to the amount of current provided from the pixel circuit PDC.

In an embodiment, the pixel circuit PDC may include first, second, third, fourth, fifth, sixth, and seventh transistors T1, T2, T3, T4, T5, T6, and T7, respectively, and first, second, and third capacitors Cst, Cbst, and Nbst, respectively. The configuration of the pixel circuit PDC should not be limited to the embodiment shown in FIG. 4. The pixel circuit PDC shown in FIG. 4 is merely one embodiment, and the configuration of the pixel circuit PDC may be changed.

In an embodiment, at least one of the first to seventh transistors T1 to T7, respectively, may include a low-temperature polycrystalline silicon (LTPS) as its semiconductor layer. At least one of the first to seventh transistors T1 to T7, respectively, may include an oxide material as its semiconductor layer. As an example, in an embodiment, each of the third and fourth transistors T3 and T4, respectively, may be an oxide semiconductor transistor, and each of the first, second, fifth, sixth, and seventh transistors T1, T2, T5, T6, and T7, respectively, may be a low-temperature polycrystalline silicon (LTPS) transistor.

In detail, the first transistor T1, which directly affects a luminance of the light emitting element ED, may include the semiconductor layer containing polycrystalline silicon with high reliability, and thus, the display device with high resolution may be implemented. Moreover, since the oxide semiconductor has a high carrier mobility and a low leakage current, the voltage drop is not large even though the driving time is long. That is, even when the pixel circuit PDC is driven at a low frequency, a change in color of the image due to the voltage drop is not large, and thus, the pixel circuit PDC may be driven at a low frequency. As described above, since the oxide semiconductor has a low leakage current, at least one of the third transistor T3 and the fourth transistor T4, which are connected to a gate electrode of the first transistor T1, may include the oxide semiconductor. Thus, the leakage current may be prevented from flowing to the gate electrode of the first transistor T1, and power consumption may be reduced.

In an embodiment, some of the first to seventh transistors T1 to T7, respectively, may be a P-type transistor, and the other of the first to seventh transistors T1 to T7, respectively, may be an N-type transistor. As an example, each of the first, second, fifth, sixth, and seventh transistors T1, T2, T5, T6, and T7, respectively, may be the P-type transistor, and each of the third and fourth transistors T3 and T4, respectively, may be the N-type transistor.

The configuration of the pixel circuit PDC should not be limited to that shown in FIG. 4. The pixel circuit PDC shown in FIG. 4 is merely an example, and the configuration of the pixel circuit PDC may be changed. As an example, in another embodiment, all the first to seventh transistors T1 to T7, respectively, may be the P-type transistor or the N-type transistor. According to another embodiment, the first, second, fifth, and sixth transistors T1, T2, T5, and T6, respectively, may be the P-type transistor, and the third, fourth, and seventh transistors T3, T4, and T7, respectively, may be the N-type transistor. It should be appreciated that the first to seventh transistors T1 to T7, respectively, may include any combination of P-type transistor and/or N-type transistor.

The j-th initialization scan line GILj, the j-th compensation scan line GCLj, the j-th write scan line GWLj, the j-th black scan line GBLj, and the j-th emission control line ECLj may transmit a j-th initialization scan signal GIj, a j-th compensation scan signal GCj, a j-th write scan signal GWj, a j-th black scan signal GBj, and a j-th emission control signal EMj to the pixel PXij, respectively. The i-th data line DLi may transmit an i-th data signal Di to the pixel PXij, where the i-th data signal Di may have a voltage level corresponding to the image signal input to the display device DD (refer to FIG. 1A).

The first driving voltage line VL1 and the second driving voltage line VL2 may transmit a first driving voltage ELVDD and a second driving voltage ELVSS to the pixel PXij, respectively. In addition, the first initialization voltage line VL3 and the second initialization voltage line VL4 may transmit a first initialization voltage VINT and a second initialization voltage VAINT to the pixel PXij, respectively.

The first transistor T1 may be connected between the first driving voltage line VL1 receiving the first driving voltage ELVDD and the light emitting element ED. The first transistor T1 may include a first electrode connected to the first driving voltage line VL1 via the fifth transistor T5, a second electrode electrically connected to a pixel electrode (or referred to as the anode) of the light emitting element ED via the sixth transistor T6, and a third electrode (e.g., the gate electrode) connected to one end (e.g., a first node N1) of the first capacitor Cst. The first transistor T1 may receive the i-th data signal Di transmitted by the i-th data line DLi in response to a switching operation of the second transistor T2 and may supply a driving current to the light emitting element ED.

The second transistor T2 may be connected between the i-th data line DLi and the first electrode of the first transistor T1. The second transistor T2 may include a first electrode connected to the i-th data line DLi, a second electrode connected to the first electrode of the first transistor T1, and a third electrode (e.g., a gate electrode) connected to the j-th write scan line GWLj. The second transistor T2 may be turned on in response to the j-th write scan signal GWj applied thereto via the j-th write scan line GWLj and may transmit the i-th data signal Di applied thereto via the i-th data line DLi to the first electrode of the first transistor T1. One end of the second capacitor Cbst may be connected to the third electrode (e.g., a gate electrode) of the second transistor T2, and the other end of the second capacitor Cbst may be connected to the first node N1.

The third transistor T3 may be connected between the second electrode of the first transistor T1 and the first node N1. The third transistor T3 may include a first electrode connected to the third electrode of the first transistor T1, a second electrode connected to the second electrode of the first transistor T1, and a third electrode (e.g., a gate electrode) connected to the j-th compensation scan line GCLj. The third transistor T3 may be turned on in response to the j-th compensation scan signal GCj applied thereto via the j-th compensation scan line GCLj and may connect the third electrode and the second electrode of the first transistor T1 to each other to allow the first transistor T1 to be connected in a diode configuration. One end of the third capacitor Nbst may be connected to the third electrode of the third transistor T3, and the other end of the third capacitor Nbst may be connected to the first node N1.

The fourth transistor T4 may be connected between the first initialization voltage line VL3 to which the first initialization voltage VINT is applied and the first node N1. The fourth transistor T4 may include a first electrode connected to the first initialization voltage line VL3 to which the first initialization voltage VINT is applied, a second electrode connected to the first node N1, and a third electrode (e.g., a gate electrode) connected to the j-th initialization scan line GILj. The fourth transistor T4 may be turned on in response to the j-th initialization scan signal GIj applied thereto via the j-th initialization scan line GILj. The turned-on fourth transistor T4 may transmit the first initialization voltage VINT to the first node N1 to initialize an electric potential of the third electrode of the first transistor T1, i.e., an electric potential of the first node N1.

The fifth transistor T5 may include a first electrode connected to the first driving voltage line VL1, a second electrode connected to the first electrode of the first transistor T1, and a third electrode (e.g., a gate electrode) connected to the j-th emission control line ECLj. The sixth transistor T6 may include a first electrode connected to the second electrode of the first transistor T1, a second electrode connected to the pixel electrode of the light emitting element ED, and a third electrode (e.g., a gate electrode) connected to the j-th emission control line ECLj.

The fifth transistor T5 and the sixth transistor T6 may be substantially simultaneously turned on in response to the j-th emission control signal EMj applied thereto via the j-th emission control line ECLj. The first driving voltage ELVDD which is applied via the turned-on fifth transistor T5 may be compensated for by the first transistor T1 which is connected in the diode configuration and which may be transmitted to the light emitting element ED via the sixth transistor T6.

The seventh transistor T7 may include a first electrode connected to the second initialization voltage line VL4 to which the second initialization voltage VAINT is applied, a second electrode connected to the second electrode of the sixth transistor T6, and a third electrode (e.g., a gate electrode) connected to the j-th black scan line GBLj. The second initialization voltage VAINT may have a voltage level which is equal to or lower than that of the first initialization voltage VINT.

The one end of the first capacitor Cst may be connected to the third electrode (e.g., a gate electrode) of the first transistor T1, and the other end of the first capacitor Cst may be connected to the first driving voltage line VL1. The cathode of the light emitting element ED may be connected to the second driving voltage line VL2 that transmits the second driving voltage ELVSS, where the second driving voltage ELVSS may have a voltage level lower than that of the first driving voltage ELVDD.

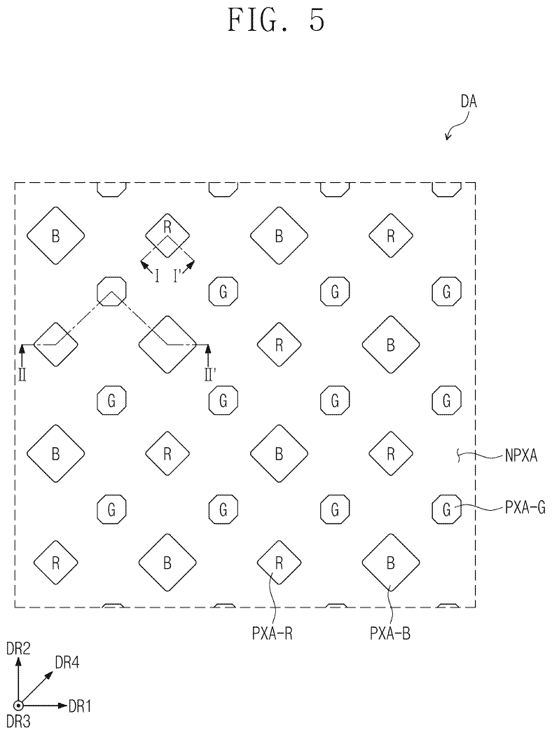

FIG. 5 is an enlarged plan view of a portion of the display area DA of the display panel, according to an embodiment, where FIG. 5 is a plan view showing the display module DM (refer to FIG. 1B) when viewed from an upper side of the display surface IS (refer to FIG. 1B) of the display module DM (refer to FIG. 1B) and shows an arrangement of light emitting areas PXA-R, PXA-G, and PXA-B.

Referring to FIG. 5, the display area DA may include first, second, and third light emitting areas PXA-R, PXA-G, and PXA-B, respectively, and a peripheral area NPXA surrounding the first, second, and third light emitting areas PXA-R, PXA-G, and PXA-B, respectively. The first, second, and third light emitting areas PXA-R, PXA-G, and PXA-B, respectively, may correspond to areas from which lights provided from light emitting elements are emitted. The first, second, and third light emitting areas PXA-R, PXA-G, and PXA-B, respectively, may be distinguished from each other by colors of the lights emitted outward from the display module DM (refer to FIG. 2).

The first light emitting area PXA-R, the second light emitting area PXA-G, and the third light emitting area PXA-B may respectively provide first, second, and third color lights, where the first, second and third color lights have colors that are different from each other. As an example, in an embodiment, the first color light may be a red light, the second color light may be a green light, and the third color light may be a blue light. However, the first, second, and third color lights should not be limited thereto or thereby.

Each of the first, second, and third light emitting areas PXA-R, PXA-G, and PXA-B, respectively, may be defined as an area through which an upper surface of the anode is exposed by a light emitting opening which is described later. The peripheral area NPXA may define a boundary between the first, second, and third light emitting areas PXA-R, PXA-G, and PXA-B, respectively, and may prevent a mixture of the colors of the lights traveling between the first, second, and third light emitting areas PXA-R, PXA-G, and PXA-B, respectively.

Each of the first, second, and third light emitting areas PXA-R, PXA-G, and PXA-B, respectively, may be provided in plural and may be repeatedly arranged in a predetermined arrangement to be disposed within the display area DA. As an example, in an embodiment, the first and third light emitting areas PXA-R and PXA-B, respectively, may be alternately arranged with each other in the first direction DR1 to form a first group. The second light emitting areas PXA-G may be arranged in the first direction DR1 to form a second group. Each of the first group and the second group may be provided in plural, and the first groups may be alternately arranged with the second groups in the second direction DR2.

One second light emitting area PXA-G may be disposed to be spaced apart from one first light emitting area PXA-R or one third light emitting area PXA-B in a fourth direction DR4, where the fourth direction DR4 may correspond to a direction between the first and second directions DR1 and DR2, respectively.

FIG. 5 shows an embodiment of the arrangement of the first, second, and third light emitting areas PXA-R, PXA-G, and PXA-B, respectively. However, the invention should not be limited, and the arrangement of the first, second, and third light emitting areas PXA-R, PXA-G, and PXA-B, respectively, may be changed in various ways. In one embodiment, the first, second, and third light emitting areas PXA-R, PXA-G, and PXA-B, respectively, may be arranged in a pentile pattern (PENTILE™) as shown in FIG. 5. According to another embodiment, the first, second, and third light emitting areas PXA-R, PXA-G, and PXA-B, respectively, may be arranged in a stripe pattern or a diamond pattern (Diamond Pixel™).

In an embodiment, each of the first, second, and third light emitting areas PXA-R, PXA-G, and PXA-B, respectively, may have a variety of shapes when viewed in a plane. As an example, each of the first, second, and third light emitting areas PXA-R, PXA-G, and PXA-B, respectively, may have a polygonal shape, a circular shape, or an oval shape. In FIG. 5, the first and third light emitting areas PXA-R and PXA-B, respectively, each having a quadrangular shape or a lozenge shape and the second light emitting area PXA-G having an octagonal shape are shown as a representative example.

In an embodiment, the first, second, and third light emitting areas PXA-R, PXA-G, and PXA-B, respectively, may have substantially the same shape as each other when viewed in the plane, or at least one of the first, second, and third light emitting areas PXA-R, PXA-G, and PXA-B, respectively, may have a shape different from the others. FIG. 5 shows an embodiment in which the first and third light emitting areas PXA-R and PXA-B, respectively, have the same shape as each other when viewed in the plane and the second light emitting area PXA-G has the shape different from those of the first and third light emitting areas PXA-R and PXA-B, respectively, as a representative example.

In an embodiment, at least one of the first, second, and third light emitting areas PXA-R, PXA-G, and PXA-B, respectively, may have a size different from those of the others when viewed in the plane. For example, the size of the first light emitting area PXA-R emitting the red light may be greater than the size of the second light emitting area PXA-G emitting the green light and may be smaller than the size of the third light emitting area PXA-B emitting the blue light. However, a size relationship between the first, second, and third light emitting areas PXA-R, PXA-G, and PXA-B, respectively, according to the colors of the lights, should not be limited thereto or thereby and may be changed in various ways depending on a design of the display module DM (refer to FIG. 2). In addition, according to an embodiment, the first, second, and third light emitting areas PXA-R, PXA-G, and PXA-B, respectively, may have substantially the same size as each other when viewed in the plane.

Meanwhile, the shape, size, and arrangement of the first, second, and third light emitting areas PXA-R, PXA-G, and PXA-B, respectively, of the display module DM (refer to FIG. 2) may be designed in various ways depending on the colors of the emitted lights, the size of the display module DM (refer to FIG. 2), and the configuration of the display module DM (refer to FIG. 2), and they should not be limited to the embodiment shown in FIG. 5.

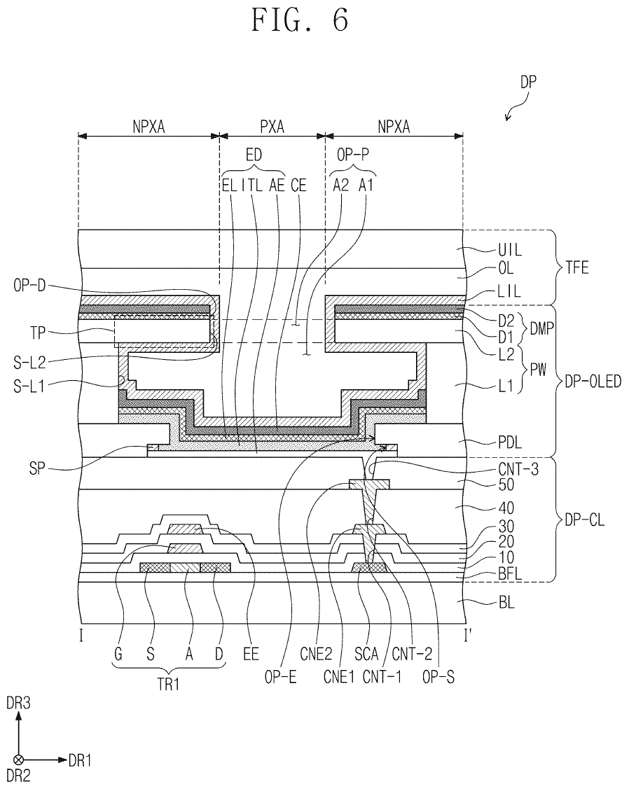

FIG. 6 is a cross-sectional view of a portion of the display panel DP, according to an embodiment. FIG. 6 is a cross-sectional view of the display panel DP taken along a line I-I′ of FIG. 5, according to an embodiment. In FIG. 6, the same reference numerals denote the same elements in FIG. 5, and thus, details of the same elements will be omitted.

FIG. 6 is an enlarged cross-sectional view of one light emitting area PXA of the display area DA (refer to FIG. 5), and the light emitting area PXA of FIG. 6 may correspond to one of the first, second, and third light emitting areas PXA-R, PXA-G, and PXA-B, respectively, of FIG. 5.

Referring to FIG. 6, the display panel DP may include the base layer BL, the circuit element layer DP-CL, the display element layer DP-OLED, and the thin film encapsulation layer TFE.

The display panel DP may include a plurality of insulating layers, a semiconductor pattern, a conductive pattern, and a signal line. An insulating layer, a semiconductor layer, and a conductive layer may be formed by a coating or depositing process. Then, the insulating layer, the semiconductor layer, and the conductive layer may be selectively patterned by a photolithography process and an etching process. The semiconductor pattern, the conductive pattern, and the signal line, which are included in the circuit element layer DP-CL and the display element layer DP-OLED, may be formed through the above processes.

The circuit element layer DP-CL may be disposed on the base layer BL and may include a buffer layer BFL, a transistor TR1, a signal transmission area SCA, first, second, third, fourth, and fifth insulating layers 10, 20, 30, 40, and 50, respectively, an electrode EE, and a plurality of connection electrodes CNE1 and CNE2.

The buffer layer BFL may be disposed on the base layer BL and may increase an adhesion between the base layer BL and the semiconductor pattern. The buffer layer BFL may include a silicon oxide layer and a silicon nitride layer, where the silicon oxide layer and the silicon nitride layer may be alternately stacked with each other.

The semiconductor pattern may be disposed on the buffer layer BFL and may include polysilicon, however, the semiconductor pattern should not be limited thereto or thereby. The semiconductor pattern may include an amorphous silicon or metal oxide. FIG. 6 shows a portion of the semiconductor pattern, where the semiconductor pattern may be further disposed in the light emitting areas PXA-R, PXA-G, and PXA-B (refer to FIG. 5). The semiconductor pattern may be arranged with a specific rule over the light emitting areas PXA-R, PXA-G, and PXA-B (refer to FIG. 5). The semiconductor pattern may have different electrical properties depending on whether it is doped or not or whether it is doped with an N-type dopant or a P-type dopant. In an embodiment, the semiconductor pattern may include a first region having a relatively high doping concentration and a second region having a relatively low doping concentration. The first region may be doped with the N-type dopant or the P-type dopant. A P-type transistor may include the first region doped with the P-type dopant.

In an embodiment, the first region may have a conductivity greater than that of the second region and may substantially serve as an electrode or a signal line. The second region may substantially correspond to an active region (or a channel) of the transistor. In other words, a portion of the semiconductor pattern may be the active region of the transistor, another portion of the semiconductor pattern may be a source or a drain of the transistor, and the other portion of the semiconductor pattern may be a conductive area.

In an embodiment, a source S, an active region A, and a drain D of the transistor TR1 may be formed from the semiconductor pattern. FIG. 6 shows a portion of the signal transmission area SCA formed from the semiconductor pattern. Although not shown in figures, the signal transmission area SCA may be connected to the drain D of the transistor TR1 in a plane.

The first, second, third, fourth, and fifth insulating layers 10, 20, 30, 40, and 50, respectively, may be disposed on the buffer layer BFL, where each of the insulating layers may be an inorganic layer or an organic layer.

The first insulating layer 10 may be disposed on the buffer layer BFL. A gate G may be disposed on the first insulating layer 10. The second insulating layer 20 may be disposed on the first insulating layer 10 and may cover the gate G. The electrode EE may be disposed on the second insulating layer 20. The third insulating layer 30 may be disposed on the second insulating layer 20 and may cover the electrode EE.

A first connection electrode CNE1 may be disposed on the third insulating layer 30. The first connection electrode CNE1 may be connected to the signal transmission area SCA via a contact hole CNT-1 defined through the first, second, and third insulating layers 10, 20, and 30, respectively. The fourth insulating layer 40 may be disposed on the third insulating layer 30 and may cover the first connection electrode CNE1. The fourth insulating layer 40 may be an organic layer.

A second connection electrode CNE2 may be disposed on the fourth insulating layer 40, where the second connection electrode CNE2 may be connected to the first connection electrode CNE1 via a contact hole CNT-2 which is defined through the fourth insulating layer 40. The fifth insulating layer 50 may be disposed on the fourth insulating layer 40 and may cover the second connection electrode CNE2. The fifth insulating layer 50 may be an organic layer.

The display element layer DP-OLED may be disposed on the circuit element layer DP-CL and may include the light emitting element ED, a pixel definition layer PDL, a barrier wall PW, and dummy patterns DMP.

The light emitting element ED may include an anode AE (or a first electrode), a conductive pattern, an electron control layer EL, and a cathode CE (or a second electrode).

The anode AE may be provided in plural and may be disposed on the fifth insulating layer 50 of the circuit element layer DP-CL. The anode AE may be a transmissive electrode, a semi-transmissive electrode, or a reflective electrode. The anode AE may have a conductivity. As an example, the anode AE may be formed from a variety of materials, such as metals, transparent conductive oxides (TCOs), or conductive polymer materials, as long as they have conductivity. The anode AE may have a single-layer or multi-layer structure. According to an embodiment, the anode AE may have a three-layer structure of indium tin oxide (ITO), silver (Ag), and indium tin oxide (ITO) and should not be limited to this embodiment.

The anode AE may be connected to the second connection electrode CNE2 via a connection contact hole CNT-3 which is defined through the fifth insulating layer 50. Accordingly, the anode AE may be electrically connected to the signal transmission area SCA via the first and second connection electrodes CNE1 and CNE2, respectively, and may be electrically connected to a corresponding circuit element.

According to an embodiment, the display panel DP may further include a sacrificial pattern SP. The sacrificial pattern SP may be disposed between the anode AE and the pixel definition layer PDL. A sacrificial opening OP-S may be defined through the sacrificial pattern SP, and a portion of an upper surface of the anode AE may be exposed through the sacrificial opening OP-S. The sacrificial opening OP-S may overlap a light emitting opening OP-E which will be described later.

The pixel definition layer PDL may be disposed on the fifth insulating layer 50 of the circuit element layer DP-CL, and may be provided with the light emitting opening OP-E defined therethrough. The light emitting opening OP-E may correspond to the anode AE, and at least a portion of the anode AE may be exposed through the light emitting opening OP-E of the pixel definition layer PDL.

In addition, the light emitting opening OP-E may correspond to the sacrificial opening OP-S of the sacrificial pattern SP. According to an embodiment, the upper surface of the anode AE may be spaced apart from the pixel definition layer PDL with the sacrificial pattern SP interposed therebetween when viewed in a cross-section, and thus, the anode AE may be prevented from being damaged in a process of forming the light emitting opening OP-E.

When viewed in a predetermined direction, a width of the light emitting opening OP-E may be smaller than a width of the sacrificial opening OP-S. In the following descriptions, the predetermined direction may indicate a vertical direction to a thickness direction, i.e., the third direction DR3, of the display panel DP. An inner side surface of the pixel definition layer PDL, which defines the light emitting opening OP-E, may be disposed closer to a center of the anode AE than an inner side surface of the sacrificial pattern SP, which defines the sacrificial opening OP-S. However, the invention should not be limited thereto or thereby. According to an embodiment, the inner side surface of the sacrificial pattern SP, which defines the sacrificial opening OP-S, may be substantially aligned with the inner side surface of the pixel definition layer PDL, which defines the corresponding light emitting opening OP-E. In this case, the light emitting area PXA may be an area of the anode AE exposed without being covered by the corresponding sacrificial opening OP-S. Additionally, according to another embodiment, the sacrificial pattern SP may be omitted.

The pixel definition layer PDL may include an inorganic insulating material. As an example, in an embodiment, the pixel definition layer PDL may include silicon nitride (SiNₓ). The pixel definition layer PDL may be disposed between the anode AE and the barrier wall PW and may block the anode AE from being electrically connected to the barrier wall PW.

The barrier wall PW may be disposed on the pixel definition layer PDL and may be provided with a barrier wall opening OP-P defined therethrough, where the barrier wall opening OP-P may overlap the light emitting opening OP-E, and where at least a portion of the anode AE may be exposed through the barrier wall opening OP-P.

The barrier wall PW may have an undercut shape in the cross-section. The barrier wall PW may include a plurality of layers sequentially stacked, and at least one of the layers may be recessed relative to adjacent layers. Accordingly, the barrier wall PW may include a tip portion TP.

In the an embodiment, the barrier wall PW may include a first barrier wall layer L1 and a second barrier wall layer L2. The first barrier wall layer L1 may be disposed on the pixel definition layer PDL, and the second barrier wall layer L2 may be disposed on the first barrier wall layer L1. As shown in FIG. 6, the first barrier wall layer L1 may have a thickness greater than a thickness of the second barrier wall layer L2, however, it should not be limited thereto or thereby. FIG. 6 shows the structure in which the barrier wall PW includes only the first barrier wall layer L1 and the second barrier wall layer L2, however, the invention should not be limited thereto or thereby. According to another embodiment, a third barrier wall layer may be disposed on the second barrier wall layer L2. In addition, the third barrier wall layer may have a thickness greater than the thickness of the second barrier wall layer L2.

The barrier wall opening OP-P defined through the barrier wall PW may be provided with a first area A1 and a second area A2, which are defined therein. The first barrier wall layer L1 may include a first inner side surface S-L1 that defines the first area A1 of the barrier wall opening OP-P, and the second barrier wall layer L2 may include a second inner side surface S-L2 that defines the second area A2 of the barrier wall opening OP-P. When viewed in the cross-section, the second inner side surface S-L2 of the second barrier wall layer L2 may be disposed closer to the center of the anode AE than the first inner side surface S-L1 of the first barrier wall layer L1. The first inner side surface S-L1 may be recessed in a direction away from the center of the anode AE when compared with the second inner side surface S-L2.

In an embodiment, the first area A1 may have a width different from a width of the second area A2, where the width of the first area A1 may be greater than the width of the second area A2. In this case, the second area A2 of the barrier wall opening OP-P may define the tip portion TP. In this case, the light emitting area PXA may be an area of the anode AE, which is exposed without being covered by the second area A2 of the corresponding barrier wall PW.

In an embodiment, the first barrier wall layer L1 may have conductivity. As an example, the first barrier wall layer L1 may include a conductive material. The conductive material may include metals, metal nitrides, transparent conductive oxides (TCOs), or combinations thereof. As an example, the metals may include gold (Au), silver (Ag), aluminum (Al), magnesium (Mg), lithium (Li), molybdenum (Mo), titanium (Ti), copper (Cu), or alloys. The metal nitrides may include titanium nitride (TiN). The transparent conductive oxides may include indium tin oxide (ITO), indium zinc oxide (IZO), zinc oxide, indium oxide, indium gallium oxide, indium gallium zinc oxide (IGZO), or aluminum zinc oxide.

In an embodiment, the second barrier wall layer L2 may be disposed on the first barrier wall layer L1 and may include a material having an etch selectivity with respect to the first barrier wall layer L1. As an example, a reactivity of the second barrier wall layer L2 to an etchant described later may be lower than that of the first barrier wall layer L1.

In an embodiment, the first barrier wall layer L1 may be recessed relative to the second barrier wall layer L2 with respect to the light emitting area. That is, the first barrier wall layer L1 may be undercut with respect to the second barrier wall layer L2. A portion of the second barrier wall layer L2, which protrudes more than the first barrier wall layer L1 to the light emitting area, may be defined as the tip portion TP in the barrier wall PW.

In an embodiment, the second barrier wall layer L2 may include a conductive material. As an example, the conductive material may include metals, metal nitrides, transparent conductive oxides (TCOs), or combinations thereof. As an example, the metals may include gold (Au), silver (Ag), aluminum (Al), magnesium (Mg), lithium (Li), molybdenum (Mo), titanium (Ti), copper (Cu), or alloys. The metal nitrides may include titanium nitride (TiN). The transparent conductive oxides may include indium tin oxide (ITO), indium zinc oxide (IZO), zinc oxide, indium oxide, indium gallium oxide, indium gallium zinc oxide (IGZO), or aluminum zinc oxide.

According to an embodiment, the second barrier wall layer L2 may include an insulating material. As an example, the second barrier wall layer L2 may include an inorganic insulating material, e.g., silicon nitride (SiNₓ) or silicon oxide (SiOₓ), however, this is merely an example. According to another embodiment, the second barrier wall layer L2 may be omitted from the barrier wall PW.

In an embodiment, the second inner side surface S-L2 of the second barrier wall layer L2 may be disposed closer to the center of the anode AE than the first inner side surface S-L1 of the first barrier wall layer L1. In other words, the first inner side surface S-L1 of the first barrier wall layer L1 may be recessed in a direction that is directed away from the center of the anode AE when compared with the second inner side surface S-L2 of the second barrier wall layer L2. Accordingly, the second barrier wall layer L2 may include a lower surface exposed without being covered by the first barrier wall layer L1.

In an embodiment, the barrier wall PW may have an undercut shape when viewed in the cross-section. As described above, the undercut shape of the barrier wall PW may be defined by a step difference between the first inner side surface S-L1 of the first barrier wall layer L1 and the second inner side surface S-L2 of the second barrier wall layer L2. However, the shape of the barrier wall PW in the cross-section should not be limited to the undercut shape, and the barrier wall PW may have a variety of shapes, such as a reverse taper shape, an overhang shape, etc.

FIG. 6 shows an embodiment where the structure in which each of the first and second inner side surfaces S-L1 and S-L2, respectively, is directed perpendicular to an upper surface of the fifth insulating layer 50 as a representative example, however, the invention should not be limited thereto or thereby.

The intermediate layer ITL may be disposed on the anode AE and may be patterned by the tip portion TP defined in the barrier wall PW. At least a portion of the intermediate layer ITL may be disposed in the light emitting opening OP-E. In various embodiments, an entire portion of the intermediate layer ITL may be disposed in the light emitting opening OP-E, or the intermediate layer ITL may be disposed in each of the barrier wall openings OP-P in addition to the light emitting openings OP-E. According to the display panel DP including the sacrificial pattern SP, the intermediate layer ITL may also be disposed in the sacrificial opening OP-S.

In an embodiment, the intermediate layer ITL may include the light emitting layer including the light emitting material. The intermediate layer ITL may further include a hole injection layer and a hole transport layer, which are disposed between the anode AE and the light emitting layer.

In an embodiment, the electron control layer EL may be disposed on the intermediate layer ITL. The electron control layer EL may further include an electron transport layer and an electron injection layer, which are disposed between the light emitting layer and the cathode CE. The electron control layer EL may be patterned by the tip portion TP which is defined in the barrier wall PW. At least a portion of the electron control layer EL may be disposed in the barrier wall opening and may also be disposed in the light emitting opening OP-E.

As described later, in an embodiment, a first dummy pattern D1 including the same material as the electron control layer EL may be disposed on an upper surface of the barrier wall PW. In detail, the first dummy pattern D1 separated from the electron control layer EL may be in contact with the upper surface of the barrier wall PW. That is, other layers may not be disposed between the electron control layer EL and the upper surface of the barrier wall PW.

In an embodiment, the cathode CE may be disposed on the electron control layer EL, where the cathode CE may be patterned by the tip portion TP which is defined in the barrier wall PW. At least a portion of the cathode CE may be disposed in the barrier wall opening OP-P. According to an embodiment, a portion of the cathode CE may also be disposed in the light emitting opening OP-E according to a thickness of the intermediate layer ITL and the electron control layer EL or a thickness of the pixel definition layer PDL.

The cathode CE may have conductivity. As an example, the cathode CE may be formed from a variety of materials, such as metals, transparent conductive oxides (TCOs), or conductive polymer materials, as long as they have conductivity.

As shown in FIG. 6, an end of the cathode CE may be in contact with the barrier wall PW.

According to an embodiment, the display panel DP may further include a capping pattern, where the capping pattern may be disposed on the cathode CE. The capping pattern may be patterned by the tip portion TP which is defined in the barrier wall PW and at least a portion of the capping pattern may be disposed in the barrier wall opening OP-P.

The dummy patterns DMP may be disposed on the barrier wall PW. The dummy patterns DMP may include the first dummy pattern D1 and a second dummy pattern D2. The first and second dummy patterns D1 and D2, respectively, may be sequentially stacked in the second direction DR2 on the second barrier layer L2 of the barrier wall PW. In detail, the first dummy pattern D1 may be in contact with an upper surface of the second barrier wall layer L2, and the second dummy pattern D2 may be disposed on the first dummy pattern D1.

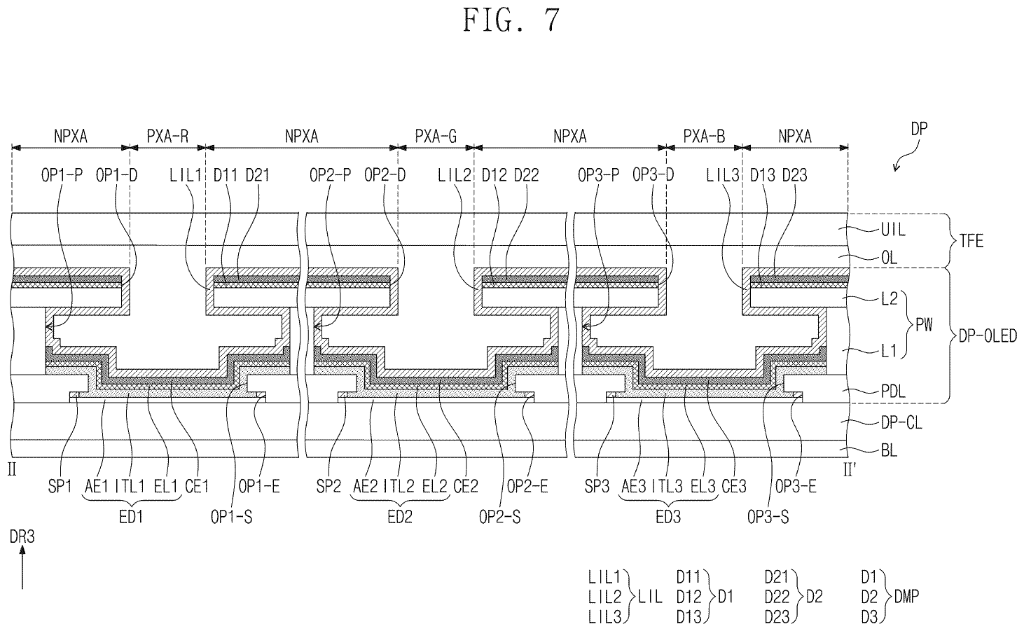

In an embodiment and as shown in FIGS. 6 and 7, the first dummy pattern D1 may entirely cover the upper surface of the second barrier wall layer L2. The second dummy pattern D2 may entirely cover the upper surface of the first dummy pattern D1. In addition, the second dummy pattern D2 may be in contact with the upper surface of the first dummy pattern D1, however, the invention should not be limited thereto or thereby. According to an embodiment, other components may be interposed between the first dummy pattern D1 and the second dummy pattern D2.

In an embodiment, the first dummy pattern D1 may include an organic material. As an example, the first dummy pattern D1 may include substantially the same material as the electron control layer EL. The first dummy pattern D1 may be substantially simultaneously formed with the electron control layer EL through a single process and may be formed separately from the electron control layer EL due to the undercut shape of the barrier wall PW.

The second dummy pattern D2 may include a conductive material. As an example, the second dummy pattern D2 may include the same material as the cathode CE. The second dummy pattern D2 may be substantially simultaneously formed with the cathode CE through a single process and may be separated from the cathode CE due to the undercut shape of the barrier wall PW.

In the embodiment where the display element layer DP-OLED further includes the capping pattern, the dummy patterns DMP may further include a third dummy pattern. The third dummy pattern may include a conductive material. As an example, the third dummy pattern may include the same material as the capping pattern. The third dummy pattern may be substantially simultaneously formed with the capping pattern through a single process and may be separated from the capping pattern due to the undercut shape of the barrier wall PW.

A dummy opening OP-D may be defined through the dummy patterns DMP. The dummy opening OP-D may overlap the light emitting opening OP-E. When viewed in the plane, the dummy patterns DMP may have a closed-line shape which surrounds the light emitting area PXA.

FIG. 6 shows an embodiment where the structure in which the inner side surfaces of the first and second dummy patterns D1 and D2, respectively, are aligned with the second inner side surface S-L2 of the second barrier wall layer L2 as a representative example. However, the invention should not be limited thereto or thereby. According to an embodiment, the first and second dummy patterns D1 and D2 may cover the second inner side surface S-L2 of the second barrier wall layer L2.

In an embodiment, the thin film encapsulation layer TFE may be disposed on the display element layer DP-OLED and may include a lower encapsulation inorganic pattern LIL, an encapsulation organic layer OL, and an upper encapsulation inorganic layer UIL.

The lower encapsulation inorganic pattern LIL may be disposed on the cathode CE and may be formed corresponding to the light emitting opening OP-E. The lower encapsulation inorganic pattern LIL may be in contact with the cathode CE, the second dummy pattern D2, and the barrier wall PW. As an example, a portion of the lower encapsulation inorganic pattern LIL may cover the cathode CE and the barrier wall PW in the barrier wall opening OP-P, and a portion of the lower encapsulation inorganic pattern LIL may cover the second dummy pattern D2 above the barrier wall PW. As an example, in an embodiment, the lower encapsulation inorganic pattern LIL may include silicon nitride (SiNₓ), however, the invention should not be limited thereto or thereby.

The encapsulation organic layer OL may cover the lower encapsulation inorganic pattern LIL and may provide a flat upper surface thereon. The upper encapsulation inorganic layer UIL may be disposed on the encapsulation organic layer OL.

The lower encapsulation inorganic pattern LIL and the upper encapsulation inorganic layer UIL may protect the display element layer DP-OLED from moisture and oxygen, and the encapsulation organic layer OL may protect the display element layer DP-OLED from a foreign substance such as dust particles.

FIG. 7 is a cross-sectional view of a portion of the display panel DP, according to an embodiment. In detail, FIG. 7 is a cross-sectional view of the display panel taken along a line II-II′ of FIG. 5.

FIG. 7 is an enlarged cross-sectional view of one first light emitting area PXA-R, one second light emitting area PXA-G, and one third light emitting area PXA-B, and the above-descriptions on the light emitting area PXA of FIG. 6 may be equally applied to the first, second, and third light emitting areas PXA-R, PXA-G, and PXA-B, respectively.

In an embodiment and referring to FIG. 7, the display element layer DP-OLED may include the light emitting elements ED1, ED2, and ED3, sacrificial patterns SP1, SP2, and SP3, the pixel definition layer PDL, the barrier wall PW, and the dummy patterns DMP.

The light emitting elements ED1, ED2, and ED3 may include a first light emitting element ED1, a second light emitting element ED2, and a third light emitting element ED3.

The first light emitting element ED1 may include a first anode AE1, a first intermediate layer ITL1, a first electron control layer EL1, and a first cathode CE1. The second light emitting element ED2 may include a second anode AE2, a second intermediate layer ITL2, a second electron control layer EL2, and a second cathode CE2. The third light emitting element ED3 may include a third anode AE3, a third intermediate layer ITL3, a third electron control layer EL3, and a third cathode CE3. The first, second, and third anodes AE1, AE2, and AE3, respectively, may be provided in plural patterns. According to an embodiment, the first intermediate layer ITL1 may provide the red light, the second intermediate layer ITL2 may provide the green light, and the third intermediate layer ITL3 may provide the blue light.

First, second, and third light emitting openings OP1-E, OP2-E, and OP3-E, respectively may be defined through the pixel definition layer PDL. The first light emitting opening OP1-E may expose at least a portion of the first anode AE1. The second light emitting opening OP2-E may expose at least a portion of the second anode AE2. The third light emitting opening OP3-E may expose at least a portion of the third anode AE3.

The sacrificial patterns SP1, SP2, and SP3 may include a first sacrificial pattern SP1, a second sacrificial pattern SP2, and a third sacrificial pattern SP3. The first sacrificial pattern SP1, the second sacrificial pattern SP2 and the third sacrificial pattern SP3 may be disposed on the upper surfaces of the first anode AE1, the second anode AE2 and the third anode AE3, respectively. The first sacrificial opening OP1-S, the second sacrificial opening OP2-S and the third sacrificial opening OP3-S may be defined through the first sacrificial pattern SP1, the second sacrificial pattern SP2 and the third sacrificial pattern SP3 to respectively correspond to the first, second, and third light emitting openings OP1-E, OP2-E, and OP3-E, respectively.

In an embodiment, first, second, and third barrier wall openings OP1-P, OP2-P, and OP3-P, respectively, may be defined through the barrier wall PW to respectively correspond to the first, second, and third light emitting openings OP1-E, OP2-E, and OP3-E, respectively. The first light emitting area PXA-R may be defined as an area of an upper surface of the first anode AE1, which is exposed through the first light emitting opening OP1-E. The second light emitting area PXA-G may be defined as an area of an upper surface of the second anode AE2, which is exposed through the second light emitting opening OP2-E. The third light emitting area PXA-B may be defined as an area of an upper surface of the third anode AE3, which is exposed through the third light emitting opening OP3-E.

Each of the first, second, and third barrier wall openings OP1-P, OP2-P, and OP3-P, respectively, may include the first area A1 (refer to FIG. 6) and the second area A2 (refer to FIG. 6). The first barrier layer L1 may include the first inner side surfaces S-L1 (refer to FIG. 6) that define the first areas A1 of the first, second, and third barrier wall openings OP1-P, OP2-P, and OP3-P, respectively, and the second barrier layer L2 may include the second inner side surfaces S-L2 (refer to FIG. 6) that define the second areas A2 of the first, second, and third barrier wall openings OP1-P, OP2-P, and OP3-P, respectively.

The first intermediate layer ITL1, the first electron control layer EL1, and the first cathode CE1 may be disposed in the first barrier wall opening OP1-P, the second intermediate layer ITL2, the second electron control layer EL2, and the second cathode CE2 may be disposed in the second barrier wall opening OP2-P, and the third intermediate layer ITL3, the third electron control layer EL3, and the third cathode CE3 may be disposed in the third barrier wall opening OP3-P.

In an embodiment, the first, second, and third intermediate layers ITL1, ITL2, and ITL3, respectively, the first, second, and third electron control layers EL1, EL2, and EL3, respectively, and the first, second, and third cathodes CE1, CE2, and CE3, respectively, may be physically separated from each other by the second barrier wall layer L2 which forms the tip portion and which may be respectively formed in the light emitting openings OP1-E, OP2-E, and OP3-E, respectively, and in the barrier wall openings OP1-P, OP2-P, and OP3-P, respectively. As shown in FIG. 7, the first, second, and third cathodes CE1, CE2, and CE3, respectively, may be in contact with the barrier wall PW, and the first, second, and third intermediate layers ITL1, ITL2, and ITL3, respectively, may be in contact with the barrier wall PW when viewed in the plane. In addition, the first, second, and third electron control layers EL1, EL2, and EL3, respectively, may be in contact with the barrier wall PW as shown in FIG. 7. FIG. 7 shows an embodiment where the structure in which the first, second, and third intermediate layers ITL1, ITL2, and ITL3, respectively, and the first, second, and third electron control layers EL1, EL2, and EL3, respectively, are in contact with the barrier wall PW as a representative example. However, in an embodiment, the first, second, and third intermediate layers ITL1, ITL2, and ITL3, respectively, and the first, second, and third electron control layers EL1, EL2, and EL3, respectively, may be spaced apart from the barrier wall PW, such that the leakage current may be prevented from occurring.

As will be described later, the first, second, and third cathodes CE1, CE2, and CE3, respectively, may be formed through the same process and may be respectively disposed in the first, second, and third barrier wall openings OP1-P, OP2-P, and OP3-P, respectively.

According to an embodiment, the intermediate layers ITL1, ITL2, and ITL3, the electron control layers EL1, EL2, and EL3, and the cathodes CE1, CE2, and CE3 may be patterned and deposited in the unit of a pixel by the tip portion which is defined in the barrier wall PW. That is, the intermediate layers ITL1, ITL2, and ITL3 may be commonly formed using an open mask, but may be easily divided into pixels by the barrier wall PW.

In a case where the intermediate layers ITL1, ITL2, and ITL3 are patterned using a fine metal mask (FMM), a support spacer protruding from a conductive barrier wall is required to support the fine metal mask. Since the fine metal mask is spaced apart from a base surface on which a patterning process is performed by a height of the barrier wall and the support spacer, there may be limitations to implementing a high resolution of the display device. In addition, as the fine metal mask is in contact with the support spacer, foreign substances may remain on the support spacer after the patterning process of the intermediate layers ITL1, ITL2, and ITL3, or the support spacer may be damaged due to the fine metal mask that gets scratches. Accordingly, a defective display panel may be manufactured.

According to an embodiment, as the display panel DP includes the barrier wall PW, the light emitting elements ED1, ED2, and ED3 may be easily and physically separated from each other. Accordingly, a leakage current or a driving error between the light emitting areas PXA-R, PXA-G, and PXA-B disposed adjacent to each other may be prevented, and the light emitting elements ED1, ED2, and ED3 may be driven independently from each other.

In particular, since the intermediate layers ITL1, ITL2, and ITL3 are patterned without masks that are in contact with components in the display area DA (refer to FIG. 1B), a defective rate of the display panel DP may be reduced, and a process reliability of the display panel DP may be improved. As the intermediate layers ITL1, ITL2, and ITL3 are patterned without the support spacer protruding from the barrier wall PW, the size of the light emitting areas PXA-R, PXA-G, and PXA-B may be reduced, and the high resolution of the display panel DP may be implemented.

In addition, when manufacturing a large-sized display panel DP, a process cost may be reduced by omitting a production of a large-sized mask, and the display panel DP may be provided with improved process reliability because the display panel DP is not affected by defects that may occur in the large-sized mask.

According to an embodiment, the electron control layers EL1, EL2, and EL3 may be formed through the same process. In addition, the cathodes CE1, CE2, and CE3 may also be formed through the same process, and the cathodes CE1, CE2, and CE3 may be formed after the electron control layers EL1, EL2, and EL3 are formed and may be disposed on the electron control layers EL1, EL2, and EL3, respectively.

That is, there is no need for additional processes involving the formation and removal of additional layers, which are required to form one of the electron control layers EL1, EL2, and EL3 or one of the cathodes CE1, CE2, and CE3 in one of the light emitting openings OP1-E, OP2-E, and OP3-E or one of the barrier wall openings OP1-P, OP2-P, and OP3-P and then to form another of the electron control layers EL1, EL2, and EL3 or another of the cathodes CE1, CE2, and CE3 in another of the light emitting openings OP1-E, OP2-E, and OP3-E or another of the barrier wall openings OP1-P, OP2-P, and OP3-P. Accordingly, the intermediate layers ITL1, ITL2, and ITL3, the electron control layers EL1, EL2, and EL3, and the cathodes CE1, CE2, and CE3 may be prevented from being damaged in the additional processes involving the formation and removal of the additional layers, and thus, the reliability of the electrical connection of the display panel may be ensured. In addition, a manufacturing process of the display panel may be simplified, and thus, a production cost and time may be reduced.

In an embodiment, the dummy patterns DMP may include a plurality of first dummy patterns D1 and a plurality of second dummy patterns D2.

The first dummy patterns D1 may include first-first, first-second, and first-third dummy patterns D11, D12, and D13, respectively, that respectively surround the first, second, and third light emitting areas PXA-R, PXA-G, and PXA-B, respectively when viewed in the plane. The dummy patterns D11, D12, and D13 may include the same material as the electron control layers EL1, EL2, and EL3, respectively, and may be formed through the same process as the electron control layers EL1, EL2, and EL3.

The second dummy patterns D2 may include second-first, second-second, and second-third dummy patterns D21, D22, and D23, respectively, that respectively surround the first, second, and third light emitting areas PXA-R, PXA-G, and PXA-B, respectively, when viewed in the plane. The dummy patterns D21, D22, and D23 may include the same material as the cathodes CE1, CE2, and CE3, respectively, and may be formed through the same process as the cathodes CE1, CE2, and CE3.

The first dummy opening OP1-D, the second dummy opening OP2-D, and the third dummy opening OP3-D respectively corresponding to the first, second, and third light emitting openings OP1-E, OP2-E, and OP3-E, respectively, may be defined through the dummy patterns DMP. The first dummy opening OP1-D may be defined by inner side surfaces of the first-first and second-first dummy patterns D11 and D21, respectively, the second dummy opening OP2-D may be defined by inner side surfaces of the first-second and second-second dummy patterns D12 and D22, respectively, and the third dummy opening OP3-D may be defined by inner side surfaces of the first-third and second-third dummy patterns D13 and D23, respectively.

In an embodiment, the thin film encapsulation layer TFE may include lower encapsulation inorganic patterns LIL1, LIL2, and LIL3, the encapsulation organic layer OL, and the upper encapsulation inorganic layer UIL. In an embodiment, the lower encapsulation inorganic patterns LIL1, LIL2, and LIL3 may include a first lower encapsulation inorganic pattern LIL1, a second lower encapsulation inorganic pattern LIL2, and a third lower encapsulation inorganic pattern LIL3. The lower encapsulation inorganic patterns LIL1, LIL2, and LIL3 may correspond to the light emitting openings OP1-E, OP2-E, and OP3-E, respectively.

The first lower encapsulation inorganic pattern LIL1 may cover the first-first and second-first dummy patterns D11 and D21, respectively, and a portion of the first lower encapsulation inorganic pattern LIL1 may be disposed in the first barrier wall opening OP1-P. The second lower encapsulation inorganic pattern LIL2 may cover the first-second and second-second dummy patterns D12 and D22, respectively, and a portion of the second lower encapsulation inorganic pattern LIL2 may be disposed in the second barrier wall opening OP2-P. The third lower encapsulation inorganic pattern LIL3 may cover the first-third and second-third dummy patterns D13 and D23, respectively, and a portion of the third lower encapsulation inorganic pattern LIL3 may be disposed in the third barrier wall opening OP3-P. The lower encapsulation inorganic patterns LIL1, LIL2, and LIL3 may be provided integrally with each other.

As described later, the lower encapsulation inorganic patterns LIL1, LIL2, and LIL3 may be formed through the same process. The lower encapsulation inorganic patterns LIL1, LIL2, and LIL3 provided integrally with each other may serve as a lower encapsulation inorganic pattern LIL and may cover the light emitting openings OP1-E, OP2-E, and OP3-E.

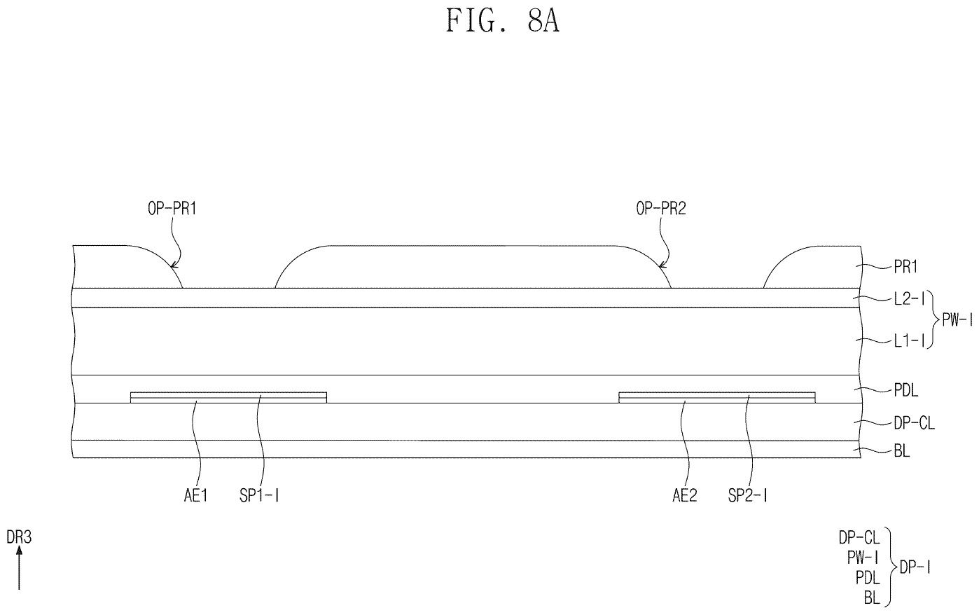

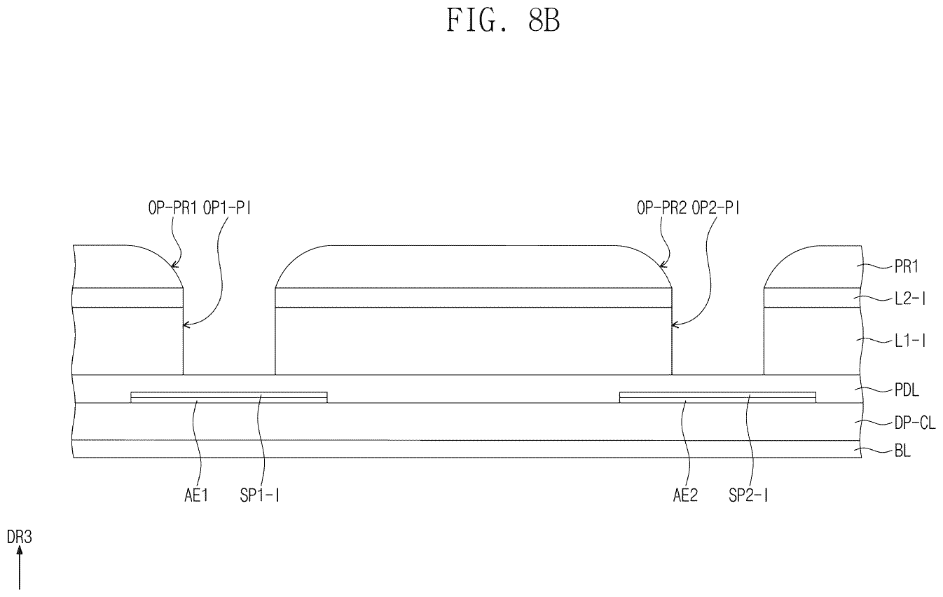

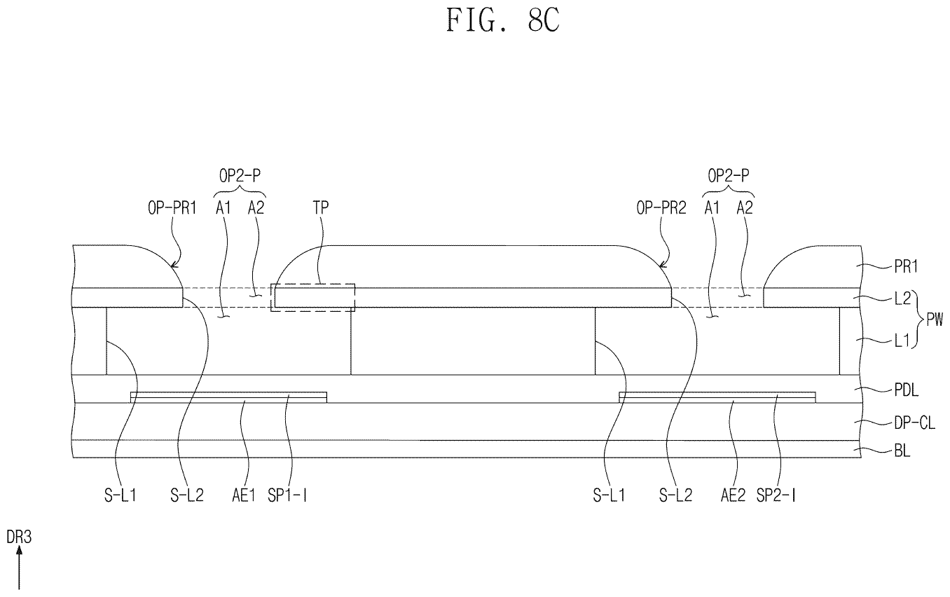

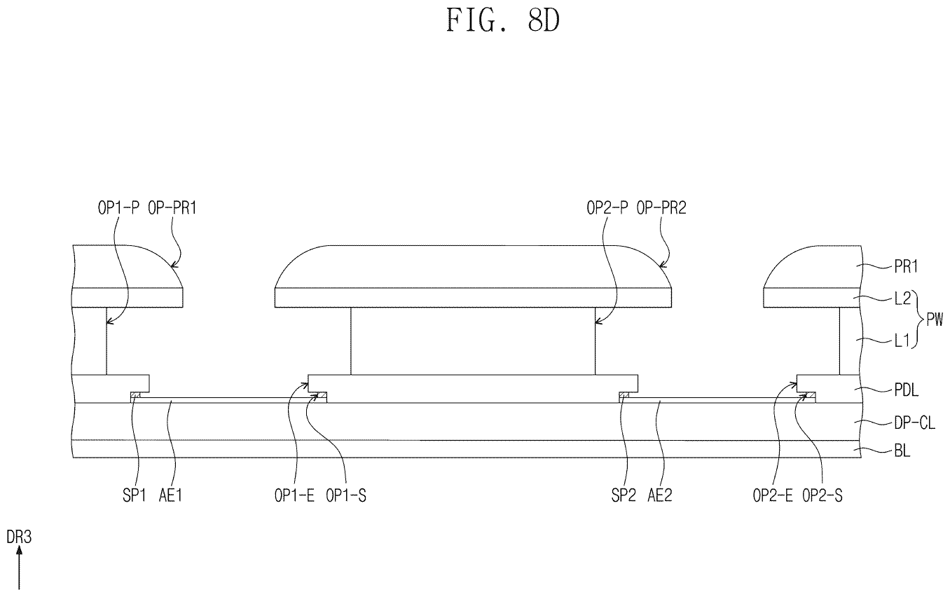

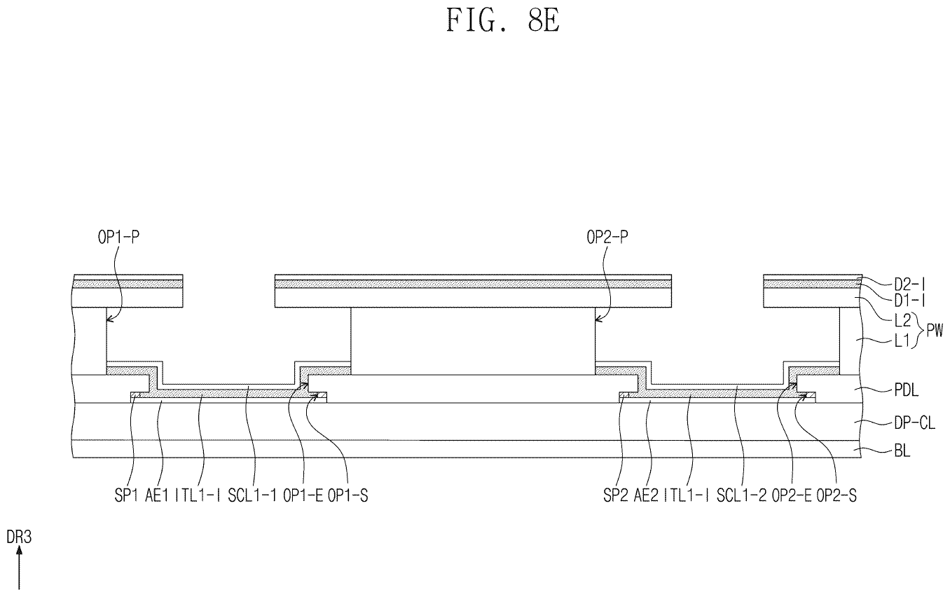

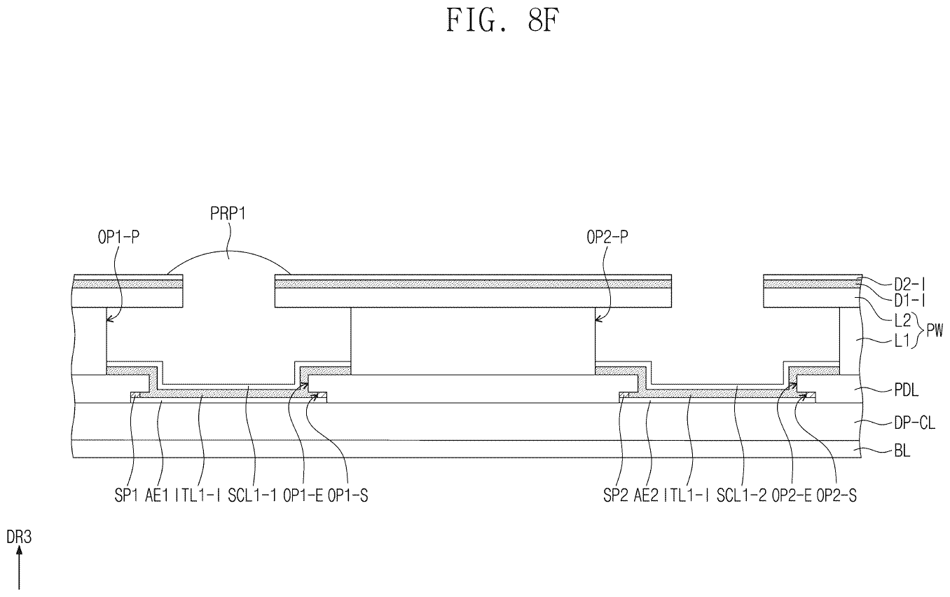

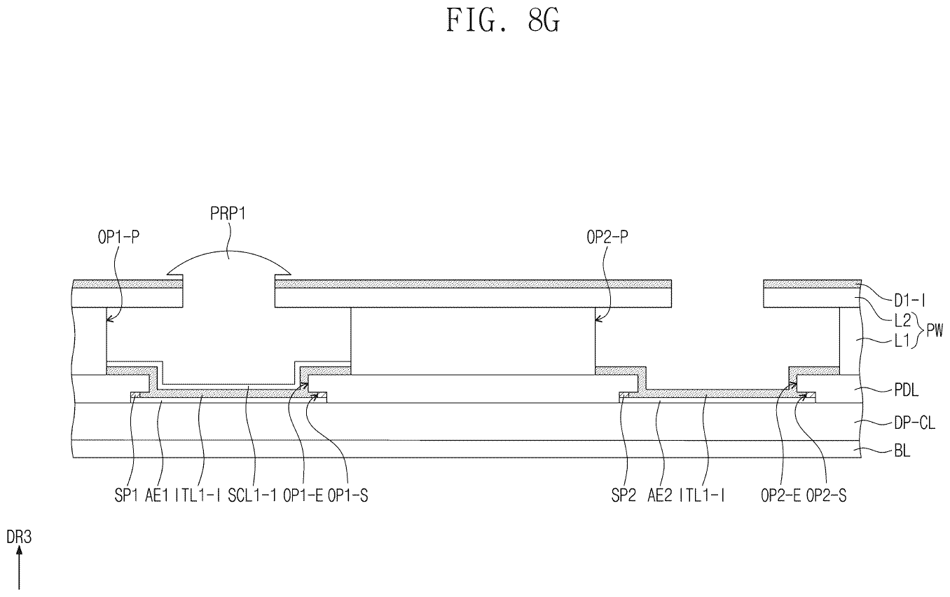

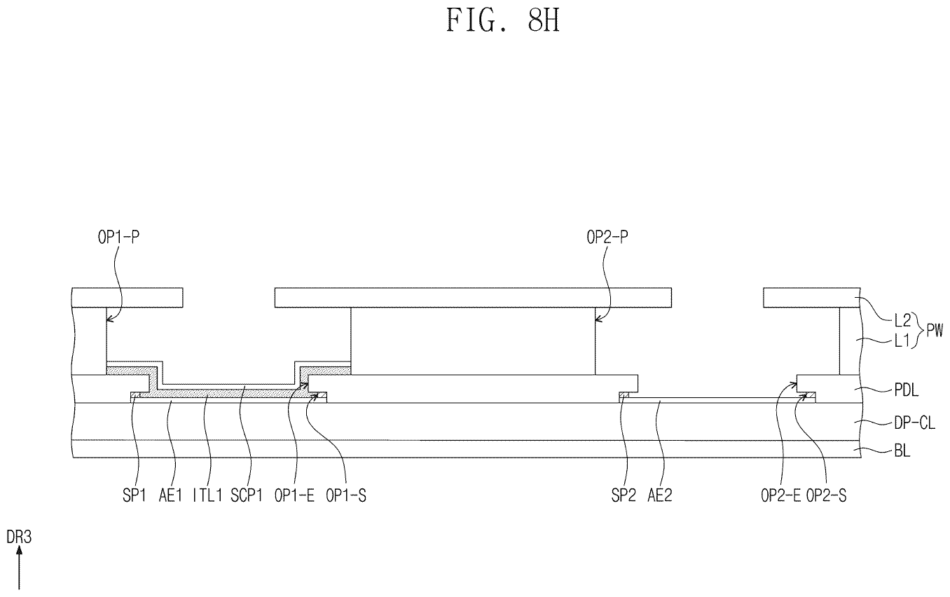

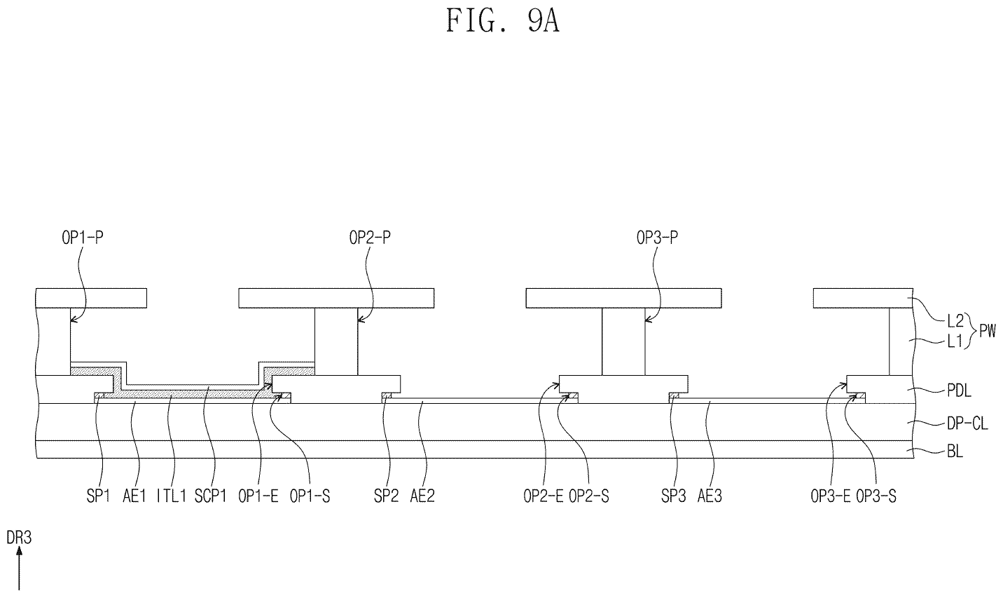

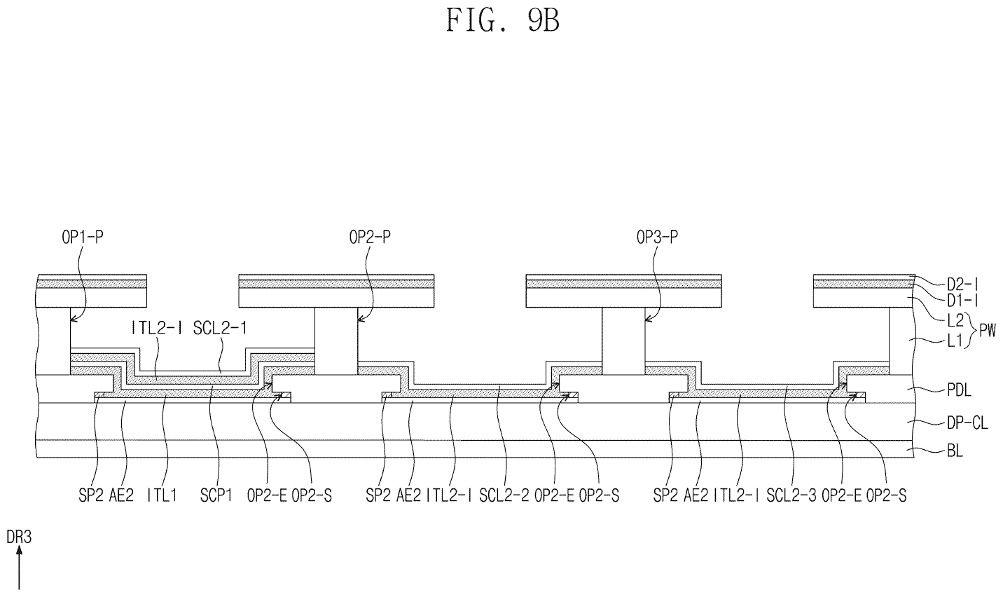

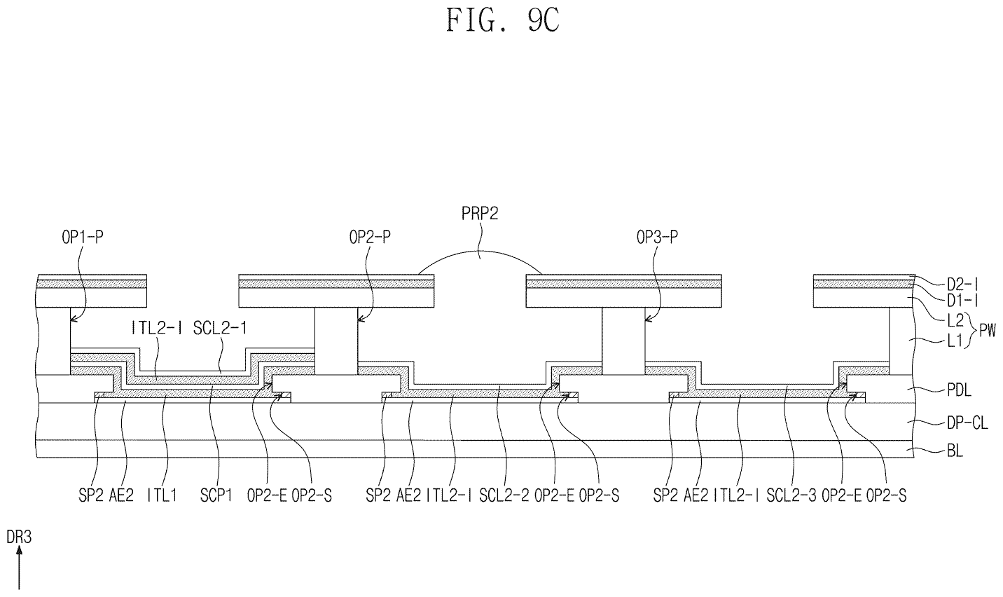

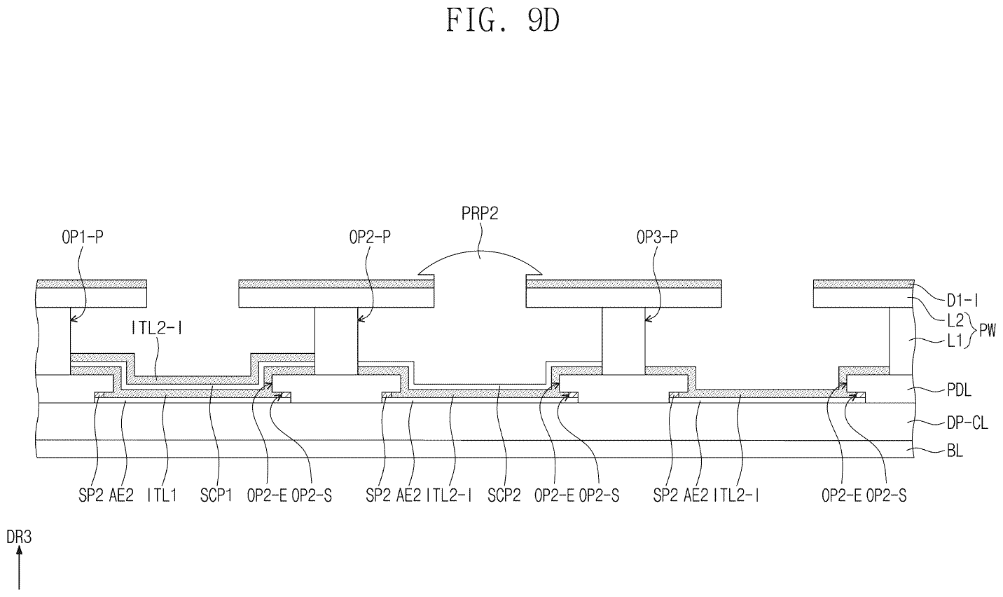

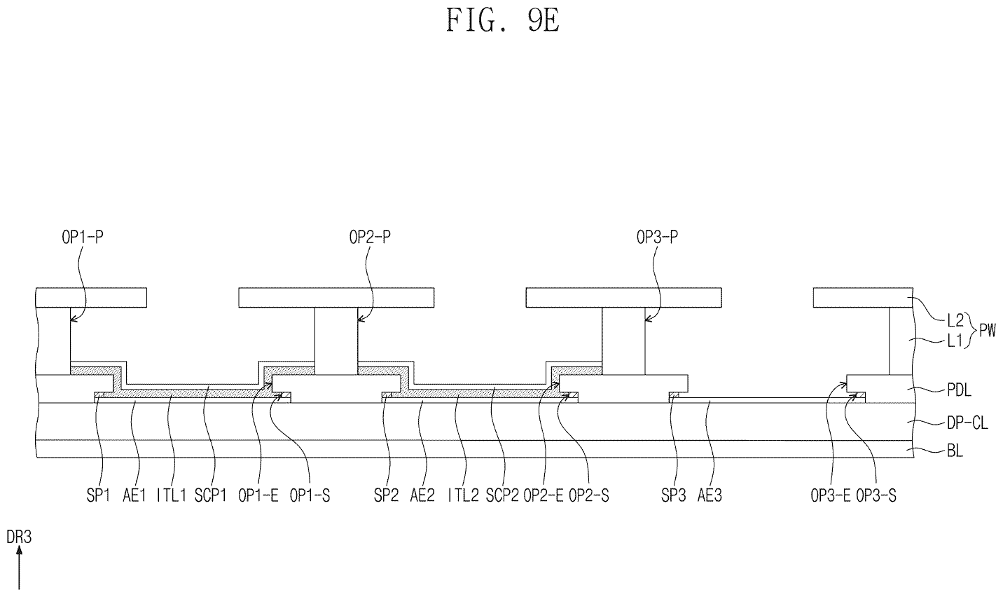

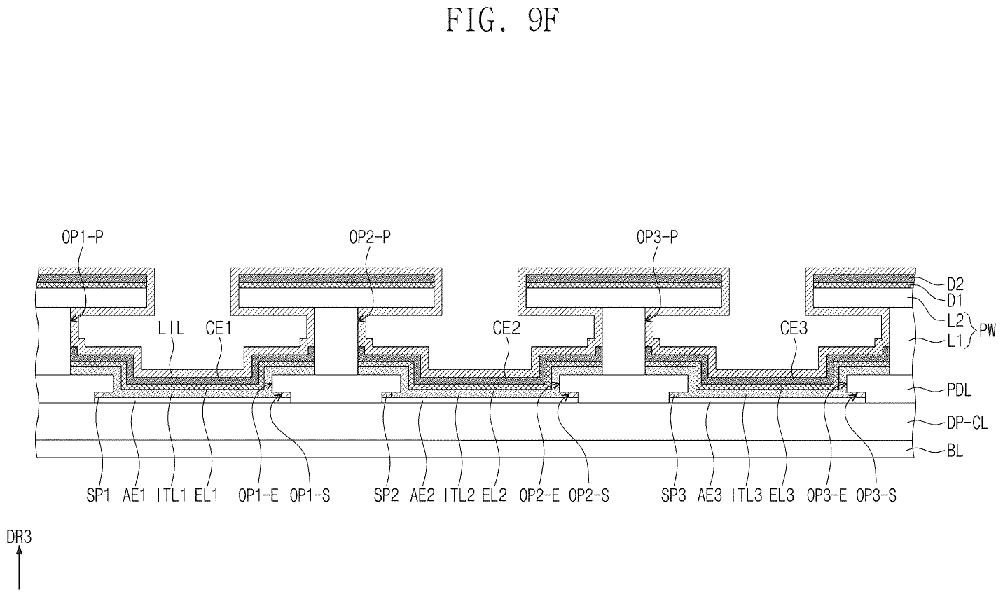

FIGS. 8A to 8H and FIGS. 9A to 9F are cross-sectional views illustrating a method of manufacturing a display panel, according to an embodiment. In FIGS. 8A to 8H and FIGS. 9A to 9F, the same/similar reference numerals denote the same/similar elements in FIGS. 1 to 7, and thus, detailed descriptions of the same elements will be omitted.

In an embodiment, the manufacturing method of the display panel may include providing a preliminary display panel including the base layer, the anode disposed on the base layer, and a preliminary pixel definition layer disposed on the base layer and covering the anode, forming the barrier wall disposed on the preliminary pixel definition layer and provided with the barrier wall openings defined therethrough, patterning the preliminary pixel definition layer to form the pixel definition layer through which the light emitting openings respectively corresponding to the barrier wall openings and exposing at least the portion of the anode are defined, and forming the first and second intermediate layers respectively including the first and second light emitting materials respectively emitting the lights having the first color and the second color which are different from the first color, wherein the first and second electron control layers respectively overlapping the first and second intermediate layers, and the first pattern separated from the first and second electron control layers and being in contact with the upper surface of the barrier wall in the barrier wall openings.

In addition, the manufacturing method of the display panel may further include forming the cathode disposed on the intermediate layer to be in contact with the barrier wall where the second pattern is separated from the cathode and is disposed on the first pattern and forming the encapsulation layer to cover the barrier wall openings.

Hereinafter, the method of forming two light emitting elements ED1 and ED2 or three light emitting elements ED1, ED2, and ED3 and the lower encapsulation inorganic pattern LIL, the encapsulation organic layer OL, and the upper encapsulation inorganic layer UIL, which cover the light emitting elements ED1, ED2, and ED3 will be described with reference to FIGS. 8A to 8H and FIGS. 9A to 9F. The display panel DP manufactured through the processes of FIGS. 8A to 8H and FIGS. 9A to 9F may correspond to portions of the display panel DP of FIG. 7.

Hereinafter, for the convenience of explanation, only two light emitting openings OP1-E and OP2-E are shown and described with reference to FIGS. 8A to 8H, and descriptions with reference to FIGS. 8A to 8H may be applied to the structure in which three or more light emitting openings are defined.

In an embodiment and referring to FIG. 8A, the manufacturing method of the display panel may include providing the preliminary display panel DP-I. The preliminary display panel DP-I may include the base layer BL, the circuit element layer DP-CL, the first and second anodes AE1 and AE2, respectively, first and second preliminary sacrificial patterns SP1-I and SP2-I, respectively, the pixel definition layer PDL, a first preliminary barrier wall layer L1-I, and a second preliminary barrier wall layer L2-I.

The circuit element layer DP-CL may be formed by a conventional circuit element manufacturing method. According to the conventional circuit element manufacturing method, an insulating layer, a semiconductor layer, and a conductive layer are formed by a coating or depositing process, the insulating layer, the semiconductor layer, and the conductive layer are selectively patterned by a photolithography process and an etching process, and thus, the semiconductor pattern, the conductive pattern, and the signal line are formed.

The first anode AE1 and the first preliminary sacrificial pattern SP1-I may be formed through the same patterning process, and the second anode AE2 and the second preliminary sacrificial pattern SP2-I may be formed through the same patterning process. The pixel definition layer PDL may be disposed on the base layer BL. The pixel definition layer PDL may cover the anodes AE1 and AE2 and the preliminary sacrificial patterns SP1-I and SP2-I.

The first preliminary barrier wall layer L1-I may be disposed on the pixel definition layer PDL. The first preliminary barrier wall layer L1-I may be formed by depositing the conductive material through a deposition process. The second preliminary barrier wall layer L2-I may be disposed on the first preliminary barrier wall layer L1-I. The second preliminary barrier wall layer L2-I may also be formed by depositing the conductive material through a deposition process. In an embodiment, the first preliminary barrier wall layer L1-I may include aluminum (Al) or molybdenum (Mo), and the second preliminary barrier wall layer L2-I may include titanium (Ti), however, the first preliminary barrier wall layer L1-I and the second preliminary barrier wall layer L2-I should not be limited thereto or thereby. The first preliminary barrier wall layer L1-I and the second preliminary barrier wall layer L2-I may form a preliminary barrier wall PW-I.

The manufacturing method of the display panel may include forming a first photoresist layer PR1 on the preliminary barrier wall PW-I, where the first photoresist layer PR1 may be formed by forming a preliminary photoresist layer on the preliminary barrier wall PW-I and patterning the preliminary photoresist layer using a photomask. A first photo opening OP-PR1 and a second photo opening OP-PR2 may be formed through the first photoresist layer PR1 by the patterning process. The first photo opening OP-PR1 may overlap the first anode AE1, and the second photo opening OP-PR2 may overlap the second anode AE2.

Referring to FIGS. 8B and 8C, the manufacturing method of the display panel may include etching the first preliminary barrier wall layer L1-I and the second preliminary barrier wall layer L2-I to form the first barrier wall layer L1 and the second barrier wall layer L2 through which the barrier wall openings OP1-P and OP2-P are defined, and thus, the barrier wall PW may be formed from the preliminary barrier wall PW-I (refer to FIG. 8A).

As shown in FIG. 8B, a first etching of the first preliminary barrier wall layer L1-I and the second preliminary barrier wall layer L2-I may include dry etching the first preliminary barrier wall layer L1-I and the second preliminary barrier wall layer L2-I using the first photoresist layer PR1 as a mask to form the preliminary barrier wall openings OP1-PI and OP2-PI through the preliminary barrier wall PW-I (refer to FIG. 8A). The preliminary barrier wall openings OP1-PI and OP2-PI may include a first preliminary barrier wall opening OP1-PI and a second preliminary barrier wall opening OP2-PI. The first preliminary barrier wall opening OP1-PI may be formed to overlap the first anode AE1, and the second preliminary barrier wall opening OP2-PI may be formed to overlap the second anode AE2.

In an embodiment, the first dry etching process may be performed in an etching environment in which the first preliminary barrier wall layer L1-I and the second preliminary barrier wall layer L2-I have substantially the same etch selectivity. Accordingly, an inner side surface of the first preliminary barrier wall layer L1-I and an inner side surface of the second preliminary barrier wall layer L2-I, which define the preliminary barrier wall openings OP1-PI and OP2-PI, may be substantially aligned with each other.

As shown in FIG. 8C, a second etching of the first preliminary barrier wall layer L1-I (refer to FIG. 8B) may include wet etching the first preliminary barrier wall layer L1-I (refer to FIG. 8B) using the first photoresist layer PR1 as a mask to form the barrier wall openings OP1-P and OP2-P from the preliminary barrier wall openings OP1-PI and OP2-PI (refer to FIG. 8B). The barrier wall openings OP1-P and OP2-P may include the first barrier wall opening OP1-P and the second barrier wall opening OP2-P. The first barrier wall opening OP1-P may be formed to overlap the first anode AE1, and the second barrier wall opening OP2-P may be formed to overlap the second anode AE2.

In an embodiment, each of the barrier wall openings OP1-P and OP2-P may include the first area A1 and the second area A2, which are sequentially defined in the thickness direction, i.e., the third direction DR3. The first barrier wall layer L1 may include the first inner side surface S-L1 that defines the first area A1 of the barrier wall openings OP1-P and OP2-P, and the second barrier wall layer L2 may include the second inner side surface S-L2 that defines the second area A2 of the barrier wall openings OP1-P and OP2-P.

In an embodiment and referring to FIGS. 6, 7, and 8C, the forming of the first barrier wall layer L1 and the second barrier wall layer L2 may include forming the tip portion TP in the second barrier wall layer L2, which protrudes from the first barrier wall layer L1 to the barrier wall openings OP1-P and OP2-P. In an embodiment, the second wet etching process may be performed in an environment in which the etch selectivity between the first preliminary barrier wall layer L1-I (refer to FIG. 8B) and the second preliminary barrier wall layer L2-I (refer to FIG. 8B) is high. Accordingly, the inner side surface of the barrier wall PW, which defines the barrier wall openings OP1-P and OP2-P, may have the undercut shape when viewed in the cross-section. In detail, as an etch rate of the first barrier wall layer L1 to the etchant is greater than an etch rate of the second barrier wall layer L2 to the etchant, the first barrier wall layer L1 may be mainly etched. Accordingly, the first inner side surface S-L1 of the first barrier wall layer L1 may be more recessed inward than the second inner side surface S-L2 of the second barrier wall layer L2. The tip portion TP may be formed in the barrier wall PW by the portion of the second barrier wall layer L2, which protrudes more than the first barrier wall layer L1.

In an embodiment and referring to FIG. 8D, the manufacturing method of the display panel may include etching the pixel definition layer PDL and etching the preliminary sacrificial patterns SP1-I and SP2-I (refer to FIG. 8C). The etching process of the pixel definition layer PDL may be performed by a dry etching process using the first photoresist layer PR1 and the barrier wall PW, e.g., the second barrier wall layer L2, as a mask. The light emitting openings OP1-E and OP2-E may be formed through the pixel definition layer PDL to correspond to the barrier wall openings OP1-P and OP2-P, where the light emitting openings OP1-E and OP2-E may include the first light emitting opening OP1-E and the second light emitting opening OP2-E.

In an embodiment, the etching process of the preliminary sacrificial patterns SP1-I and SP2-I (refer to FIG. 8C) may be performed by a wet etching process using the first photoresist layer PR1 and the barrier wall PW, e.g., the second barrier wall layer L2, as a mask. The sacrificial openings OP1-S and OP2-S may be formed through the sacrificial patterns SP1 and SP2, which are formed by etching the preliminary sacrificial patterns SP1-I and SP2-I (refer to FIG. 8C), to overlap the light emitting openings OP1-E and OP2-E.

The sacrificial patterns SP1 and SP2 may include the first sacrificial pattern SP1 and the second sacrificial pattern SP2. The first sacrificial opening OP1-S may be formed through the first sacrificial pattern SP1 to overlap the first light emitting opening OP1-E, and the second sacrificial opening OP2-S may be formed through the second sacrificial pattern SP2 to overlap the second light emitting opening OP2-E. At least a portion of the first anode AE1 may be exposed through the first sacrificial opening OP1-S and the first light emitting opening OP1-E without being covered by the first sacrificial pattern SP1 and the pixel definition layer PDL, and at least a portion of the second anode AE2 may be exposed through the second sacrificial opening OP2-S and the second light emitting opening OP2-E without being covered by the second sacrificial pattern SP2 and the pixel definition layer PDL.

The etching process of the sacrificial patterns SP1 and SP2 may be performed in an environment in which the etch selectivity between the sacrificial patterns SP1 and SP2 and the anodes AE1 and AE2 is high, and thus, the anodes AE1 and AE2 may be prevented from being etched with the sacrificial patterns SP1 and SP2. That is, as the sacrificial patterns SP1 and SP2 having an etch rate higher than the anodes AE1 and AE2 are disposed between the pixel definition layer PDL and the anodes AE1 and AE2, the anodes AE1 and AE2 may be prevented from being etched and thus, damaged in the etching process.

In an embodiment and referring to FIGS. 8E to 8H, the manufacturing method of the display panel may include forming a first preliminary intermediate layer ITL1-I and first protective layers SCL1-1 and SCL1-2 in the barrier wall openings OP1-P and OP2-P after removing the first photoresist layer PR1 (refer to FIG. 8D).

Referring to FIG. 8E, the forming of the first preliminary intermediate layer ITL1-I may include depositing the first preliminary intermediate layer ITL1-1, where the depositing of the first preliminary intermediate layer ITL1-I may include a thermal evaporation process.

In an embodiment, the first preliminary intermediate layer ITL1-I may include a hole control layer (the hole injection layer or the hole transport layer) and the light emitting layer which includes the light emitting material. After the hole control layer is formed, the light emitting layer may be formed on the hole control layer.

The first preliminary intermediate layer ITL1-I may be formed on the anodes AE1 and AE2 and may be divided into portions by the tip portion formed in the barrier wall PW and may be disposed in the light emitting openings OP1-E and OP2-E and the barrier wall openings OP1-P and OP2-P. The first preliminary intermediate layer ITL1-I may be formed to be in contact with the second barrier wall layer L2 in the barrier wall openings OP1-P and OP2-P. When the first preliminary intermediate layer ITL1-I is formed, a first dummy layer D1-I which is separated from the first preliminary intermediate layer ITL1-I may be formed on the barrier wall PW.

The forming of the first protective layers SCL1-1 and SCL1-2 may include depositing the first protective layers SCL1-1 and SCL1-2. In an embodiment, the depositing of the first protective layers SCL1-1 and SCL1-2 may include a thermal evaporation process, where when the first protective layers SCL1-1 and SCL1-2 are deposited by the thermal evaporation process, the light emitting layer of the first preliminary intermediate layer ITL1-I may be prevented from being exposed to plasma.

In an embodiment, the first protective layers SCL1-1 and SCL1-2 may be formed on the first preliminary intermediate layer ITL1-I. The first protective layers SCL1-1 and SCL1-2 may be divided into portions by the tip portion formed in the barrier wall PW and may be disposed in the barrier wall openings OP1-P and OP2-P. The first protective layers SCL1-1 and SCL1-2 may be formed to be spaced apart from the second barrier wall layer L2 in the barrier wall openings OP1-P and OP2-P when viewed in the plane. In the process of forming the first protective layers SCL1-1 and SCL1-2, a second dummy layer D2-I which is separated from the first protective layers SCL1-1 and SCL1-2 may be formed on the barrier wall PW.

In an embodiment, a first-first protective layer SCL1-1 may be formed on the first preliminary intermediate layer ITL1-I in the first barrier wall opening OP1-P, and a first-second protective layer SCL1-2 may be formed on the first preliminary intermediate layer ITL1-I in the second barrier wall opening OP2-P.

According to an embodiment, the protective layers SCL1-1 and SCL1-2 may include a material with an etch selectivity to the barrier wall PW. As an example, the protective layers SCL1-1 and SCL1-2 may include silver (Ag). However, the invention should not be limited thereto or thereby, and the protective layers SCL1-1 and SCL1-2 may include other materials rather than silver (Ag).

In an embodiment and referring to FIG. 8F, the manufacturing method of the display panel may include forming a first photoresist pattern PRP1 covering the first light emitting opening OP1-E and the first barrier wall opening OP1-P. The first photoresist pattern PRP1 may not overlap the second light emitting opening OP2-E.

The first photoresist pattern PRP1 may prevent the first-first protective layer SLCL1-1 from being etched in an etching process described later.

In an embodiment and referring to FIG. 8G, the manufacturing method of the display panel may include removing a portion of the first protective layers SCL1-1 and SCL1-2.

According to an embodiment, the portion of the first protective layers SCL1-1 and SCL1-2 (refer to FIG. 8F) may be removed by a wet etching process. In this case, an etchant used for the wet etching process may react solely with the first protective layers SCL1-1 and SCL1-2 (refer to FIG. 8F) and not with the barrier wall. As an example, when the first protective layers SCL1-1 and SCL1-2 (refer to FIG. 8F) include silver (Ag) and the barrier wall PW includes aluminum (Al), the etchant may selectively etch only the silver (Ag) and may not etch the aluminum (Al).

In an embodiment and as shown in the figures, the first photoresist pattern PRP1 may cover the first-first protective layer SCL1-1 and may prevent the first-first protective layer SCL1-1 from contacting the etchant, and thus, the first-first protective layer SCL1-1 may not be removed. However, since the first-second protective layer SCL1-2 (refer to FIG. 8F) is not covered by the first photoresist pattern PRP1, the first-second protective layer SCL1-2 (refer to FIG. 8F) may be removed by the etchant. In this case, the remaining first-first protective layer SCL1-1 may form the first protective pattern SCP1.

When the portion of the first protective layers SCL1-1 and SCL1-2 (refer to FIG. 8F) disposed on the barrier wall PW is removed, a predetermined gap may be formed between the first photoresist pattern PRP1 and the first preliminary intermediate layer ITL1-I.

The portion of the first protective layers SCL1-1 and SCL1-2 (refer to FIG. 8F) may be removed by a dry etching process without being limited to the above descriptions.

In an embodiment and referring to FIG. 8H, the manufacturing method of the display panel may include removing the first preliminary intermediate layer ITL1-I and the first photoresist pattern PRP1. According to an embodiment, the first preliminary intermediate layer ITL1-I and the first photoresist pattern PRP1 may be removed by a strip process, however, the process of removing the first preliminary intermediate layer ITL1-I and the first photoresist pattern PRP1 should not be particularly limited.

The first preliminary intermediate layer ITL1-I and the first protective pattern SCP1, which are covered by the first photoresist pattern PRP1, may not be removed in the removing process. That is, the first preliminary intermediate layer ITL1-I formed in the second light emitting opening OP2-E and the third light emitting opening OP3-E (See FIG. 9A) may be removed, but the first preliminary intermediate layer ITL1-I and the first protective pattern SCP1 formed in the first light emitting opening OP1-E may not be removed. The remaining first preliminary intermediate layer ITL1-I may form the first intermediate layer ITL1.

Hereinafter, for the convenience of explanation, FIGS. 9A to 9F show three light emitting openings OP1-E, OP2-E, and OP3-E to explain differences between the light emitting elements ED1, ED2, and ED3 (refer to FIG. 7), and this may be applied to four or more light emitting elements.

In an embodiment and referring to FIGS. 9A and 9B, the manufacturing method of the display panel may include forming a second preliminary intermediate layer ITL2-I and second protective layers SCL2-1, SCL2-2, and SCL2-3 in the barrier wall openings OP1-P.

The forming of the second preliminary intermediate layer ITL2-I may include depositing the second preliminary intermediate layer ITL2-I and may include a thermal evaporation process.

The forming of the second protective layers SCL2-1, SCL2-2, and SCL2-3 may include depositing the second protective layers SCL2-1, SCL2-2, and SCL2-3, where the depositing of the second protective layers SCL2-1, SCL2-2, and SCL2-3 may include a thermal evaporation process.

In an embodiment, the second preliminary intermediate layer ITL2-I may be formed on the anodes AE1, AE2, and AE3. The second preliminary intermediate layer ITL2-I may be divided into portions by the tip portion formed in the barrier wall PW and may be disposed in the barrier wall openings OP1-P, OP2-P, and OP3-P and may overlap the light emitting openings OP1-E and OP2-E, and OP3-E. The second preliminary intermediate layer ITL2-I may be formed to be in contact with the second barrier wall layer L2 in the barrier wall openings OP1-P, OP2-P, and OP3-P. In the process of forming the second preliminary intermediate layer ITL2-I, the first dummy layer D1-I may be formed on the barrier wall PW and may be spaced apart from the second preliminary intermediate layer ITL2-I.

In an embodiment, the second preliminary intermediate layer ITL2-I may be formed on the first protective pattern SCP1 in the first barrier wall opening OP1-P, may be formed on the second anode AE2 in the second barrier wall opening OP2-P, and may be formed on the third anode AE3 in the third barrier wall opening OP3-P.

The second protective layers SCL2-1, SCL2-2, and SCL2-3 may be formed on the second preliminary intermediate layer ITL2-I. The second protective layers SCL2-1, SCL2-2, and SCL2-3 may be divided into portions by the tip portion formed in the barrier wall PW and may be disposed in the barrier wall openings OP1-P, OP2-P, and OP3-P, respectively. The second protective layers SCL2-1, SCL2-2, and SCL2-3 may be formed to be spaced apart from the second barrier wall layer L2 in the barrier wall openings OP1-P, OP2-P, and OP3-P when viewed in the plane. In the process of forming the second protective layers SCL2-1, SCL2-2, and SCL2-3, the second dummy layer D2-I may be formed on the barrier wall PW and may be separated from the second protective layers SCL2-1, SCL2-2, and SCL2-3.

In an embodiment, a second-first protective layer SCL2-1 may be formed on the second preliminary intermediate layer ITL2-I in the first barrier wall opening OP1-P, a second-second protective layer SCL2-2 may be formed on the second preliminary intermediate layer ITL2-I in the second barrier wall opening OP2-P, and a second-third protective layer SCL2-3 may be formed on the second preliminary intermediate layer ITL2-I in the third barrier wall opening OP3-P.

In an embodiment and referring to FIG. 9C, the manufacturing method of the display panel may include forming a second photoresist pattern PRP2 covering the second light emitting opening OP2-E and the second barrier wall opening OP2-P. The second photoresist pattern PR2 may not overlap the first light emitting opening OP1-E and the third light emitting opening OP3-E.

The second photoresist pattern PRP2 may prevent the second-second protective layer SCL2-2 from being etched in the following etching process.

In an embodiment and referring to FIG. 9D, the manufacturing method of the display panel may include removing a portion of the second protective layers SCL2-1, SCL2-2, and SCL2-3 (refer to FIG. 9C). The second protective layers SCL2-1, SCL2-2, and SCL2-3 (refer to FIG. 9C) may include the same material as the first protective layers SCL1-1 and SCL1-2 (refer to FIG. 8E) and may be partially removed through the same process as the first protective layers SCL1-1 and SCL1-2 (refer to FIG. 8E).

As shown in figures, since the second photoresist pattern PRP2 covers the second-second protective layer SCL2-2 (refer to FIG. 9C) and prevents the second-second protective layer SCL2-2 (refer to FIG. 9C) from being in contact with the etchant, the second-second protective layer SCL2-2 (refer to FIG. 9C) may not be removed. However, since the second-first protective layer SCL2-1 (refer to FIG. 9C) and the second-third protective layer SCL2-3 (refer to FIG. 9C) are not covered by the second photoresist pattern PRP2, the second-first protective layer SCL2-1 (refer to FIG. 9C) and the second-third protective layer SCL2-3 (refer to FIG. 9C) may be removed by the etchant. In this case, the remaining second-second protective layer SCL2-2 (refer to FIG. 9C) may form the second protective pattern SCP2.

In an embodiment and referring to FIG. 9E, the manufacturing method of the display panel may include removing the second preliminary intermediate layer ITL2-I (refer to FIG. 9D) and the second photoresist pattern PRP2 (refer to FIG. 9D). According to an embodiment, the second preliminary intermediate layer ITL2-I (refer to FIG. 9D) and the second photoresist pattern PRP2 (refer to FIG. 9D) may be removed by a strip process, however, the process of removing the second preliminary intermediate layer ITL2-I (refer to FIG. 9D) and the second photoresist pattern PRP2 (refer to FIG. 9D) should not be particularly limited.

In an embodiment, the second preliminary intermediate layer ITL2-I (refer to FIG. 9D) and the second protective pattern SCP2, which are covered by the second photoresist pattern PRP2 (refer to FIG. 9D), may not be removed in the removing process. That is, the second preliminary intermediate layer ITL2-I (refer to FIG. 9D) formed in the first light emitting opening OP1-E and the third light emitting opening OP3-E may be removed, however, the second preliminary intermediate layer ITL2-I (refer to FIG. 9D) and the second protective pattern SCP2, which are formed in the second light emitting opening OP2-E, may not be removed. The remaining second preliminary intermediate layer ITL2-I (refer to FIG. 9D) may form the second intermediate layer ITL2.

Although not shown in figures, the third intermediate layer ITL3 (refer to FIG. 9F) disposed in the third light emitting opening OP3-E may be formed through substantially the same process as the second intermediate layer ITL2 disposed in the second light emitting opening OP2-E. However, the process of forming the third intermediate layer ITL3 (refer to FIG. 9F) may be performed differently and should not be particularly limited.

In addition, in an embodiment, a third protective pattern may be disposed on the third intermediate layer ITL3 (refer to FIG. 9F) as the first protective pattern SCP1 disposed on the first intermediate layer ITL1 and the second protective pattern SCP2 disposed on the second intermediate layer ITL2. The first protective pattern SCP1, the second protective pattern SCP2, and the third protective pattern may protect the first, second, and third intermediate layers ITL1, ITL2, and ITL3 (refer to FIG. 9F) from being exposed to the outside and damaged before the first, second, and third electron control layers EL1, EL2, and EL3 (refer to FIG. 9F) are formed.

In an embodiment and referring to FIG. 9F, the manufacturing method of the display panel may include forming the electron control layers EL1, EL2, and EL3, forming the cathodes CE1, CE2, and CE3, and forming the lower encapsulation inorganic pattern LIL after the third intermediate layer ITL3 is formed in the third light emitting opening OP3-E.

According to an embodiment, the first electron control layer EL1, the second electron control layer EL2, and the third electron control layer EL3 may be formed on the first, second, and third intermediate layers ITL1, ITL2, and ITL3, respectively. Prior to forming the electron control layers EL1, EL2, and EL3, removing the first protective pattern SCP1 (refer to FIG. 9E), the second protective pattern SCP2 (refer to FIG. 9E), and the third protective pattern may be performed.

The forming of the first, second, and third electron control layers EL1, EL2, and EL3 may include a thermal evaporation process.

In an embodiment, in the process of forming the first, second, and third electron control layers EL1, EL2, and EL3, the first, second, and third electron control layers EL1, EL2, and EL3 may be divided from each other by the tip portions formed in the barrier wall PW and may be respectively disposed in the barrier wall openings OP1-P, OP2-P, and OP3-P.

In the process of forming the first, second, and third electron control layers EL1, EL2, and EL3, the first dummy pattern D1 may be formed to be spaced apart from the first, second, and third electron control layers EL1, EL2, and EL3 disposed on the barrier wall PW.

That is, the first, second, and third electron control layers EL1, EL2, and EL3, respectively, which are respectively disposed in the barrier wall openings OP1-P, OP2-P, and OP3-P, respectively, may be substantially simultaneously formed through the same process.

According to an embodiment, the first, second, and third cathodes CE1, CE2, and CE3 may be respectively formed on the first electron control layer EL1, the second electron control layer EL2, and the third electron control layer EL3. The forming of the first, second, and third cathodes CE1, CE2, and CE3 may include a thermal evaporation process.

In the process of forming the first, second, and third cathodes CE1, CE2, and CE3, the first, second, and third cathodes CE1, CE2, and CE3 may be divided from each other by the tip portions formed in the barrier wall PW and may be respectively disposed in the barrier wall openings OP1-P, OP2-P, and OP3-P.

In the process of forming the first, second, and third cathodes CE1, CE2, and CE3, the second dummy pattern D2 which is spaced apart from the cathodes CE1, CE2, and CE3 may be formed on the barrier wall PW.

That is, the first, second, and third cathodes CE1, CE2, and CE3, respectively, which are respectively disposed in the barrier wall openings OP1-P, OP2-P, and OP3-P may be substantially simultaneously formed through the same process.

According to the embodiment, the lower encapsulation inorganic layer LIL may be formed to cover the first barrier wall opening OP1-P, the second barrier wall opening OP2-P, and the third barrier wall opening OP3-P. The lower encapsulation inorganic pattern LIL may be formed through a chemical vapor deposition (CVD) process. The lower encapsulation inorganic pattern LIL may be formed on the barrier wall PW and the second dummy pattern D2, and a portion of the lower encapsulation inorganic pattern LIL may be formed in the first, second, and third barrier wall openings OP1-P, OP2-P, and OP3-P.

That is, according to an embodiment, the first, second, and third electron control layers EL1, EL2, and EL3, respectively, which are respectively disposed in the first, second, and third barrier wall openings OP1-P, OP2-P, and OP3-P, respectively, may be substantially simultaneously formed through the same process. In addition, after the electron control layers EL1, EL2, and EL3 are formed, the first, second, and third cathodes CE1, CE2, and CE3, respectively, which are respectively disposed on the first, second, and third electron control layers EL1, EL2, and EL3, respectively, may be substantially simultaneously formed. Further, after the cathodes CE1, CE2, and CE3 are formed, the lower encapsulation inorganic pattern LIL may be continuously formed to cover each of the cathodes CE1, CE2, and CE3.

According to an embodiment, there is no need for additional processes involving the formation and removal of additional layers, which are required to form one of the electron control layers EL1, EL2, and EL3 or one of the cathodes CE1, CE2, and CE3 in one of the light emitting openings OP1-E, OP2-E, and OP3-E or one of the barrier wall openings OP1-P, OP2-P, and OP3-P and then to form another of the electron control layers EL1, EL2, and EL3 or another of the cathodes CE1, CE2, and CE3 in another of the light emitting openings OP1-E, OP2-E, and OP3-E or another of the barrier wall openings OP1-P, OP2-P, and OP3-P. Accordingly, the intermediate layers ITL1, ITL2, and ITL3, the electron control layers EL1, EL2, and EL3, and the cathodes CE1, CE2, and CE3 may be prevented from being damaged in the additional processes involving the formation and removal of the additional layers, and thus, the reliability of the electrical connection of the display panel may be ensured. In addition, a manufacturing process of the display panel may be simplified, and thus, a production cost and time may be reduced.

In an embodiment, the manufacturing method of the display panel may further include the forming of the encapsulation organic layer OL (refer to FIG. 7) on the lower encapsulation inorganic pattern LIL and the forming of the upper encapsulation inorganic layer UIL (refer to FIG. 7) on the encapsulation organic layer OL (refer to FIG. 7).

Consequently, as shown in FIG. 7, the first dummy pattern D1, the second dummy pattern D2, the lower encapsulation inorganic pattern LIL, the encapsulation organic layer OL (refer to FIG. 7), and the upper encapsulation inorganic layer UIL (refer to FIG. 7) may be sequentially formed on the upper surface of the barrier wall PW. However, according to an embodiment, other layers may be disposed between the first dummy pattern D1 and the lower encapsulation inorganic pattern LIL in addition to the second dummy pattern D2, and the invention should not be particularly limited thereto.

Although embodiments of the invention have been described, it is understood that the invention should not be limited to these embodiments but various changes and modifications can be made by one of ordinary skill in the art within the spirit and scope of the invention as hereinafter claimed. Therefore, the scope of the invention should not be limited to any single embodiment described herein or otherwise. Moreover, embodiments or parts of the embodiments may be combined in whole or in part without departing from the 10 scope of the invention.

What is claimed is:

1. A display panel comprising:
a base layer;
a pixel definition layer disposed on the base layer and having a light emitting opening defined therethrough;
a barrier wall disposed on the pixel definition layer, having a conductivity, and having a barrier wall opening defined therethrough and corresponding to the light emitting opening;
a light emitting element disposed in the light emitting opening and comprising an anode, an intermediate layer disposed on the anode, an electron control layer disposed on the intermediate layer, and a cathode disposed on the electron control layer and connected to the barrier wall;
a first pattern spaced apart from the electron control layer, being in contact with an upper surface of the barrier wall, and comprising a same material as the electron control layer; and
a second pattern spaced apart from the cathode, disposed on the first pattern, and comprising a same material as the cathode.

2. The display panel of claim 1, wherein the first pattern entirely covers the upper surface of the barrier wall, and the second pattern entirely covers an upper surface of the first pattern.

3. The display panel of claim 1, wherein the second pattern is in contact with an upper surface of the first pattern.

4. The display panel of claim 1, further comprising an encapsulation layer covering the light emitting element, wherein the encapsulation layer entirely covers an upper surface of the second pattern.

5. The display panel of claim 4, wherein the encapsulation layer entirely covers a side surface of the first pattern and a side surface of the second pattern.

6. The display panel of claim 1, wherein the barrier wall has an undercut shape when viewed in a cross-section.

7. The display panel of claim 1, further comprising:
a first encapsulation layer covering the light emitting element;
a monomer covering the first encapsulation layer; and
a second encapsulation layer covering the monomer.

8. The display panel of claim 1, wherein the intermediate layer comprises:
a hole control layer disposed on the anode; and
a light emitting layer disposed on the hole control layer and comprising a light emitting material.

9. A display panel comprising:
a base layer;
a pixel definition layer disposed on the base layer and including a plurality of light emitting openings defined therethrough and including a first light emitting opening and a second light emitting opening, wherein the plurality of light emitting openings are spaced apart from each other;
a barrier wall disposed on the pixel definition layer, having a conductivity, and including a plurality of barrier wall openings defined therethrough, wherein the plurality of barrier wall openings correspond to the plurality of light emitting openings;
a first light emitting element disposed in the first light emitting opening and comprising a first anode, a first intermediate layer disposed on the first anode and comprising a first light emitting material generating a light having a first color, a first electron control layer disposed on the first intermediate layer, and a first cathode disposed on the first electron control layer and connected to the barrier wall;
a second light emitting element disposed in the second light emitting opening and comprising a second anode, a second intermediate layer disposed on the second anode and comprising a second light emitting material generating a light having a second color, a second electron control layer disposed on the second intermediate layer, and a second cathode disposed on the second electron control layer and connected to the barrier wall;
a first pattern spaced apart from the first electron control layer and the second electron control layer, being in contact with an upper surface of the barrier wall, and comprising a same material as the first electron control layer and the second electron control layer; and
a second pattern spaced apart from the first cathode and the second cathode, disposed on the first pattern, and comprising a same material as the first cathode and the second cathode.

10. The display panel of claim 9, further comprising an encapsulation layer covering the first light emitting opening, the second light emitting opening, and the barrier wall, wherein the encapsulation layer entirely covers an upper surface of the second pattern.

11. The display panel of claim 9, wherein the first pattern entirely covers the upper surface of the barrier wall, and the second pattern entirely covers an upper surface of the first pattern.

12. The display panel of claim 9, wherein the first intermediate layer comprises:
a first hole control layer disposed on the first anode; and
a first light emitting layer disposed on the first hole control layer and comprising the first light emitting material, and
wherein the second intermediate layer comprises:
a second hole control layer disposed on the second anode; and
a second light emitting layer disposed on the second hole control layer and comprising the second light emitting material.

13. A method of manufacturing a display panel, comprising:
providing a preliminary display panel comprising a base layer, an anode disposed on the base layer, and a preliminary pixel definition layer disposed on the base layer and covering the anode;
forming a barrier wall on the preliminary pixel definition layer, through which a plurality of barrier wall openings is defined;
patterning the preliminary pixel definition layer to form a pixel definition layer through which a plurality of light emitting openings respectively corresponding to the plurality of barrier wall openings and exposing at least a portion of the anode is defined, wherein the plurality of light emitting openings include a first light emitting opening and a second light emitting opening; and
forming a first intermediate layer and a second intermediate layer respectively comprising a first light emitting material and a second light emitting material respectively generating lights having a first color and a second color which are different from each other, a first electron control layer and a second electron control layer overlapping the first intermediate layer and the second intermediate layer, and a first pattern separated from the first electron control layer and the second electron control layer and being in contact with an upper surface of the barrier wall via the plurality of barrier wall openings, wherein the first pattern is substantially simultaneously formed with the first electron control layer, and the second intermediate layer is formed after the first intermediate layer is formed and before the first pattern is formed.

14. The method of claim 13, further comprising forming a cathode disposed on the first intermediately layer and the second intermediate layer and being in contact with the barrier wall, and a second pattern separated from the cathode and disposed on the first pattern, wherein the second pattern is substantially simultaneously formed with the cathode.

15. The method of claim 13, further comprising:
forming a first preliminary intermediate layer on the anode and the barrier wall;
forming a first protective layer on the first preliminary intermediate layer;
forming a first photoresist pattern covering the first light emitting opening;
removing the first protective layer to form a first protective pattern; and
removing the first preliminary intermediate layer and the first photoresist pattern to form the first intermediate layer.

16. The method of claim 15, further comprising:
forming a second preliminary intermediate layer on the anode, the first intermediate layer, and the barrier wall;
forming a second protective layer on the second preliminary intermediate layer;
forming a second photoresist pattern covering the second light emitting opening;
removing the second protective layer to form a second protective pattern; and
removing the second preliminary intermediate layer and the second photoresist pattern to form the second intermediate layer, wherein the first protective pattern and the second protective pattern are removed, and a second pattern, a first cathode disposed in the first light emitting opening, and a second cathode disposed in the second light emitting opening are formed.

17. The method of claim 15, wherein the first protective layer is formed by a thermal evaporation process.

18. The method of claim 15, wherein the first protective layer is removed by a wet etching process.

19. The method of claim 13, further comprising forming an encapsulation layer covering the plurality of barrier wall openings, wherein the encapsulation layer covers both of the first light emitting opening and the second light emitting opening which is spaced apart from the first light emitting opening.

20. The method of claim 13, wherein the forming of the barrier wall comprises:
forming a first layer on the pixel definition layer;
forming a second layer on the first layer;
patterning the first layer and the second layer to form a barrier wall pattern; and
patterning the barrier wall pattern to form an undercut in the barrier wall pattern.
